(19) United States
(12) Patent Application Publication
(10) Pub. No.: US 2026/0096328 A1
(43) Pub. Date: Apr. 2, 2026

(54) DISPLAY APPARATUS, ELECTRONIC DEVICE INCLUDING THE DISPLAY APPARATUS, AND METHOD OF MANUFACTURING DISPLAY APPARATUS

(71) Applicant: Samsung Display Co., Ltd., Yongin-si (KR)

(72) Inventors: BOKWANG SONG, Yongin-si (KR); Sungho Choi, Yongin-si (KR); CHAUNGI CHOI, Yongin-si (KR); YOUNGCHAN KIM, Yongin-si (KR); JAEHO YOU, Yongin-si (KR); HYUN JIN CHO, Yongin-si (KR)

(21) Appl. No.: 19/339,011

(22) Filed: Sep. 24, 2025

(30) Foreign Application Priority Data
Sep. 30, 2024 (KR) 10-2024-0133021
Feb. 7, 2025 (KR) 10-2025-0016126

(51) Int. Cl. H10K 59/80; H10K 59/12

(52) U.S. Cl. CPC H10K 59/80515; H10K 59/1201; H10K 59/8792

(57) ABSTRACT

A display apparatus may include a substrate, a first electrode above (e.g., on) the substrate, a second electrode opposite to (e.g., facing) the first electrode, and an intermediate layer between the first electrode and the second electrode and including an organic light-emitting layer, wherein the first electrode includes a first region having a first height with respect to an upper surface of the substrate, and second regions, each of the second regions having a second height that is lower than the first height.

### CROSS-REFERENCE TO RELATED APPLICATION

The present application claims priority to and the benefit of Korean Patent Application No. 10-2024-0133021, filed on Sep. 30, 2024, and Korean Patent Application No 10-2025-0016126, filed on Feb. 7, 2025, in the Korean Intellectual Property Office, the entire disclosures of both of which are incorporated herein by reference.

### BACKGROUND

### 1. Field

One or more embodiments of the present disclosure relate to a display apparatus and a method of manufacturing such a display apparatus.

### 2. Description of the Related Art

Recently, the applications of display apparatuses have become increasingly diverse. Moreover, as the display apparatuses become thinner and lighter, their range of use has expanded across a broader array of fields.

Further, as the range of applications for display apparatuses continues to grow and technologies utilizing display apparatuses advance, there is increasing demand for improved or enhanced image quality and higher resolution in such display apparatuses.

As display apparatuses evolve toward higher resolutions, challenges emerge in improving or enhancing image quality and precisely or suitably controlling optical characteristics.

### SUMMARY

One or more aspects of embodiments of the present disclosure are directed toward a display apparatus that improves or enhances image quality characteristics and precisely or suitably controls optical characteristics and a method of manufacturing the display apparatus.

Additional aspects of embodiments will be set forth in part in the description which follows and, in part, will be apparent from the description or may be learned by practice of the presented embodiments of the disclosure.

One or more embodiments of the present disclosure provide a display apparatus including a first electrode arranged above (e.g., on) the substrate, a second electrode opposite to (e.g., facing) the first electrode, and an intermediate layer arranged between the first electrode and the second electrode and including an organic light-emitting layer, wherein the first electrode includes a first region having a first height with respect to an upper surface of the substrate and second regions, each of the second regions having a second height with a smaller value than the first height (e.g., having a second height that is lower than the first height).

In one or more embodiments, the first region may be arranged between the second regions arranged on at least opposite sides of the first region (e.g., between two of the second regions that are opposite to each other).

In one or more embodiments, the first region may be surrounded by the second regions (e.g., the second regions may be around or surround the first region).

In one or more embodiments, the first region may be spaced and/or apart (e.g., spaced apart or separated) from the second regions.

In one or more embodiments, the first electrode may include a base layer, a first pattern layer on the base layer, and a second pattern layer on the base layer, the first region may correspond to the base layer and the first pattern layer, and the second region may correspond to the base layer and the second pattern layer.

In one or more embodiments, a thickness value of the first pattern layer may be greater than a thickness value of the second pattern layer (e.g., the first pattern layer may be thicker than the second pattern layer).

In one or more embodiments, the first pattern layer and the second pattern layer may be spaced and/or apart (e.g., spaced apart or separated) from each other.

In one or more embodiments, a light-blocking member may further be arranged above (e.g., on) the second electrode, the light-blocking member may include an opening region to allow light generated in the intermediate layer to pass therethrough, and the first region and the second regions of the first electrode may overlap the opening region.

In one or more embodiments, the first region of the first electrode may correspond to a region including a central portion of the opening region, and the second regions may be around (e.g., surround) the first region.

In one or more embodiments, the first region may be connected to the second regions.

In one or more embodiments, the first pattern layer and the second pattern layer may be connected to each other.

In one or more embodiments, at least one or more intermediate regions may be arranged between the first region and the second region, and the at least one or more intermediate regions may include regions having at least one or more heights between the first height and the second height.

In one or more embodiments, the display apparatus may further include an intermediate pattern layer arranged between the first pattern layer and the second pattern layer and corresponding to the intermediate region.

In one or more embodiments, the display apparatus may further include one or more insulating (e.g., electrically insulating) layers arranged between the substrate and the first electrode.

In one or more embodiments, the display apparatus may further include one or more thin-film transistors arranged between the substrate and the first electrode.

In one or more embodiments, the display apparatus may further include a heterogeneous layer arranged between the base layer and the first pattern layer and containing a material different from a material of the first pattern layer.

In one or more embodiments, the first pattern layer may be connected to at least the base layer.

In one or more embodiments, the first pattern layer may correspond to at least an upper surface and a side surface of the heterogeneous layer.

In one or more embodiments, the first pattern layer may cover the heterogeneous layer.

In one or more embodiments, the heterogeneous layer may contain an insulating (e.g., electrically insulating) material.

In one or more embodiments, the heterogeneous layer may contain a transparent (e.g., substantially transparent) inorganic insulating (e.g., electrically insulating) material.

One or more embodiments of the present disclosure provide a display apparatus including a substrate, a first electrode arranged on the substrate, a second electrode opposite to (e.g., facing) the first electrode, and an organic light-emitting layer arranged between the first electrode and the second electrode.

The first electrode may include a base layer having one or more curved portions and a pattern layer on the base layer.

In one or more embodiments, the curved portion may include a convex surface protruded in a direction toward the second electrode.

In one or more embodiments, an upper surface of the pattern layer opposite to (e.g., facing) the second electrode may have a flat surface (e.g., a substantially flat surface) in at least one region of the upper surface of the pattern layer.

In one or more embodiments, the curved portion and the pattern layer may not overlap each other.

In one or more embodiments, the pattern layer may be arranged between the curved portions that are arranged on opposite sides of the pattern layer.

In one or more embodiments, the pattern layer may be surrounded by the curved portions.

In one or more embodiments, the curved portion may be arranged between portions of the pattern layer, which are arranged on opposite sides of the curved portion.

In one or more embodiments, each of the one or more curved portions may be surrounded by the pattern layer.

One or more embodiments of the present disclosure provide a method of manufacturing a display apparatus that may include a first electrode, a second electrode, and an intermediate layer arranged between the first and second electrodes, all of which are arranged above (e.g., on) a substrate, the method including forming the first electrode that includes forming a base layer of the first electrode on the substrate, and forming a pattern layer having one or more patterns on the base layer.

In one or more embodiments, the forming of the pattern layer may include forming at least two or more distinct pattern layers.

In one or more embodiments, the method may further include forming a heterogeneous layer in at least one region between the one or more patterns and the base layer, the heterogeneous layer including a material different from a material of the one or more patterns.

In one or more embodiments, a type (kind) of an etching process in forming the one or more patterns may be different from a type (kind) of an etching process in the forming of the heterogeneous layer.

One or more embodiments of the present disclosure provide an electronic device including a processor to execute one or more applications and a display apparatus to implement one or more images through the processor, wherein the display apparatus includes a substrate, a first electrode arranged above (e.g., on) the substrate, a second electrode opposite to (e.g., facing) the first electrode, and an intermediate layer arranged between the first electrode and the second electrode and including an organic light-emitting layer, wherein the first electrode includes a first region having a first height with respect to an upper surface of the substrate; and second regions, each of the second regions having a second height with a smaller value than the first height (e.g., having a second height that is lower than the first height).

In one or more embodiments, the electronic device may further include a power module to generate a power to operate a memory that stores data information for an operation of the processor or the display apparatus or to operate the electronic device.

In one or more embodiments, the electronic device may be applied to an image display electronic device, a wearable electronic device, or a vehicle electronic device.

One or more embodiments of the present disclosure provide an electronic device including a processor to execute one or more applications and a display apparatus to implement one or more images through the processor, wherein the display apparatus includes a substrate, a first electrode arranged above (e.g., on) the substrate, a second electrode opposite to (e.g., facing) the first electrode, and an intermediate layer arranged between the first electrode and the second electrode and including an organic light-emitting layer, wherein the first electrode includes a base layer having one or more curved portions, and a pattern layer on the base layer.

For example, one or more embodiments as described herein provide a comprehensive approach to improving or enhancing the performance and manufacturability of display apparatuses, for example, those incorporating organic light-emitting layers. By introducing structural variations in electrode design, such as a first region having a greater height and second regions having a lesser height relative to the substrate, these embodiments enable enhanced control over optical characteristics and image quality. Additional features, such as curved portions, heterogeneous layers, and multi-pattern configurations or arrangements, further contribute to the fine-tuning of light emission and device efficiency. The disclosed manufacturing methods may support precise formation of these structures, facilitating integration into a wide range of electronic devices. As such, the present disclosure offers a versatile and scalable solution applicable to wearable electronics, vehicle displays, and/or other advanced image display systems.

Other aspects, effects, and/or embodiments of the present disclosure will become more apparent from the accompanying drawings, the appended claims and equivalents thereof, and the detailed description of the present disclosure.

### BRIEF DESCRIPTION OF THE DRAWINGS

The above and other aspects and features of certain embodiments of the present disclosure will be more apparent from the following description taken in conjunction with the accompanying drawings, in which:

FIG. 1 is a cross-sectional view schematically illustrating a display apparatus according to one or more embodiments of the present disclosure;

FIG. 2 is a cross-sectional view schematically illustrating a display apparatus according to one or more embodiments of the present disclosure;

FIG. 3 is a schematic plan view of FIG. 2, viewed from one direction;

FIG. 4 is a cross-sectional view schematically illustrating a display apparatus according to one or more embodiments of the present disclosure;

FIG. 5 is a schematic plan view of FIG. 4, viewed from one direction;

FIG. 6 is a cross-sectional view schematically illustrating a display apparatus according to one or more embodiments of the present disclosure;

FIG. 7 is a schematic plan view of FIG. 6, viewed from one direction;

FIG. 8 is a cross-sectional view schematically illustrating a display apparatus according to one or more embodiments of the present disclosure;

FIG. 9 is a schematic plan view of FIG. 8, viewed from one direction;

FIG. 10 is a cross-sectional view schematically illustrating a display apparatus according to one or more embodiments of the present disclosure;

FIG. 11 is a schematic plan view of FIG. 10, viewed from one direction;

FIG. 12 is a cross-sectional view schematically illustrating a display apparatus according to one or more embodiments of the present disclosure;

FIG. 13 is a schematic plan view of FIG. 12, viewed from one direction;

FIGS. 14-19 are views schematically describing a method of manufacturing a display apparatus according to one or more embodiments of the present disclosure;

FIG. 20 is a cross-sectional view schematically illustrating a display apparatus according to one or more embodiments of the present disclosure;

FIG. 21 is a cross-sectional view schematically illustrating a display apparatus according to one or more embodiments of the present disclosure;

FIGS. 22-28 are views schematically describing a method of manufacturing a display apparatus according to one or more embodiments of the present disclosure;

FIG. 29 is a diagram describing an electronic device to which the display apparatus according to one or more embodiments of the present disclosure is applied; and

FIG. 30 is a drawing illustrating one or more suitable examples of the electronic device of FIG. 29.

### DETAILED DESCRIPTION

While the subject matter of the present disclosure is capable of one or more suitable modifications and alternative forms, embodiments thereof are shown by way of example in the drawings and will herein be described in more detail. Aspects, features, and characteristics of embodiments of the present disclosure and methods to achieve them will be more clearly understood from embodiments described herein in more detail with reference to the drawings. However, the present disclosure is not limited to the embodiments disclosed hereinafter but may be implemented in one or more suitable forms.

The utilization of “may” if (e.g., when) describing embodiments of the present disclosure refers to “one or more embodiments of the present disclosure.”

In the context of the present application and unless otherwise defined, the terms “use,” “using,” and “used” may be considered synonymous with the terms “utilize,”“utilizing,”and “utilized,”respectively.

As used herein, the singular forms “a,” “an,” and “the” are intended to include the plural forms as well, unless the context clearly indicates otherwise. The singular expression includes the plural expression unless the context clearly dictates otherwise.

As used herein, the term “and/or” or “or” includes any and all combinations of one or more of the associated listed items.

Throughout the present disclosure, the expressions, such as “at least one of,” “one of,” and “selected from,” if (e.g., when) preceding a list of elements, modify the entire list of elements and do not modify the individual elements of the list. For example, “at least one of a, b, or c,” “at least one selected from among a, b, and c,” “at least one selected from among a to c,” and/or the like indicates only a, only b, only c, both (e.g., simultaneously) a and b, both (e.g., simultaneously) a and c, both (e.g., simultaneously) b and c, all of a, b, and c, or variations thereof.

As utilized herein, the terms “substantially,” “about,” or similar terms are used as terms of approximation and not as terms of degree and are intended to account for the inherent deviations in measured or calculated values that would be recognized by those of ordinary skill in the art. “About” as used herein is inclusive of the stated value and refers to as being within an acceptable range of deviation for the particular value as determined by one of ordinary skill in the art, considering the measurement in question and the error associated with measurement of the particular quantity (e.g., the limitations of the measurement system). For example, “about” may refer to as being within one or more standard deviations or within ±30%, ±20%, ±10%, or ±5% of the stated value. Also, it should be understood that, even if (e.g., when) the terms “about,” “approximately,” or “substantially” are not expressly recited in a given element (e.g., a claim element), the scope of such element is intended to include variations that are insubstantial or within the understanding of one of ordinary skill in the art. For example, numerical values and ranges provided herein are intended to include tolerances and measurement uncertainties that would be recognized by those skilled in the art, and the elements (e.g., claim elements) should be construed accordingly to encompass such equivalents.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, for example, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in the present disclosure is intended to include all higher numerical limitations subsumed therein. Accordingly, Applicant reserves the right to amend the disclosure, including the claims, to expressly recite any sub-range subsumed within the ranges expressly recited herein.

In the present disclosure, the terms “first,” “second,” and/or the like have been used to distinguish one component from another, rather than limitative in all aspects.

It will be further understood that the terms “includes,” “has,” “including,” and/or “having” used herein specify the presence of stated features or components, but do not preclude the presence or addition of one or more other features or components. For example, it should be understood that the term “comprise(s)/comprising,” “include(s)/including,” or “have/has/having” specifies the presence of stated features, integers, steps, operations, elements, and/or components, but do not preclude the presence or addition of one or more other features, integers, steps, operations, elements, components, and/or groups thereof. Also, the terms “comprise(s)/comprising,” “include(s)/including,” “have/has/having,” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof.

In the present disclosure, if (e.g., when) a film, a region, or a component is referred to as being “on” or “above” another film, region, or component, it may be directly or indirectly on or directly or indirectly above the other unit, region, or component. For example, intervening films, regions, or components may be present therebetween. In contrast, if (e.g., when) a film, a region, or a component is referred to as being “directly on” or “directly above” another film, region, or component, there are no intervening films, regions, or components present therebetween.

Sizes of components in the drawings may be exaggerated or reduced for convenience of description. For example, the size and thickness of each component illustrated in the drawings may be arbitrarily represented for convenience of description, and thus, embodiments of the present disclosure are not necessarily limited thereto.

In the present disclosure, an x-axis, a y-axis, and a z-axis are not limited to three axes of the rectangular coordinate system and may be interpreted in a broader sense. For example, the x-axis, the y-axis, and the z-axis may be perpendicular to one another or may represent different directions that are not perpendicular to one another.

In the context of the present disclosure and unless otherwise defined, plan view is an orthographic projection of a three-dimensional object from the position of a horizontal plane that intersects the object. For example, it is a top-down view, showing the layout and spatial relationships of one or more elements within the object or structure. A plan view based on a z-axis (thickness) direction refers to a top-down view of the object, as if (e.g., when) looking directly down onto the surface from above. In this context, the z-axis direction is perpendicular or normal to the horizontal plane defined by x-axis and y-axis directions.

If (e.g., when) certain embodiments may be implemented otherwise, a specific process sequence may be performed differently from the described sequence. For example, two consecutively described processes may be performed substantially at the same time or performed in an order opposite to the described order.

Hereinafter, one or more embodiments of the present disclosure will be described in more detail with reference to the accompanying drawings, but if (e.g., when) describing with reference to the drawings, substantially equal or corresponding components will be referred to as the same reference numerals, and redundant descriptions thereof may not be provided.

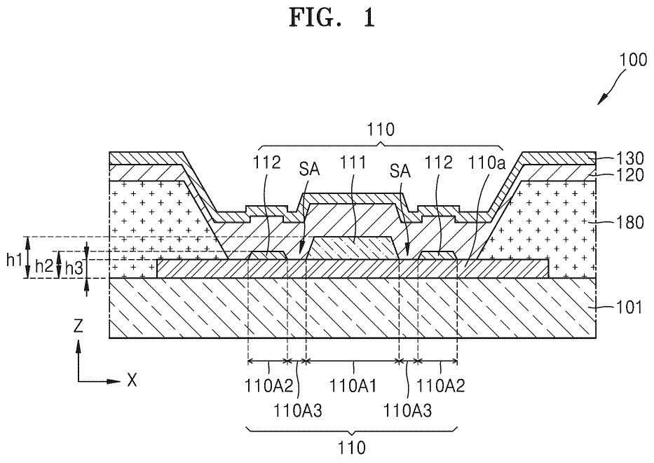

FIG. 1 is a cross-sectional view schematically illustrating a display apparatus according to one or more embodiments of the present disclosure.

Referring to FIG. 1, a display apparatus 100 may include a substrate 101, a first electrode 110, a second electrode 130, and an intermediate layer 120.

In one or more embodiments, the display apparatus 100 may further include a pixel defining film 180.

The substrate 101 may include one or more suitable materials. In more detail, the substrate 101 may be formed or composed of glass, metal, and/or organic materials.

In one or more embodiments, the substrate 101 may be formed or composed of a flexible material. For example, the substrate 101 may be easily or suitably flexible, bendable, foldable, or rollable.

In one or more embodiments, the substrate 101 may be made of ultra-thin glass, metal, and/or plastic. For example, if (e.g., when) utilizing plastic, the substrate 101 may contain polyimide (PI), and as another example, the substrate 101 may include at least one selected from among polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polycarbonate, triacetate cellulose, and cellulose acetate propionate.

In one or more embodiments, the substrate 101 may have a structure with one or more layers, such as a multi-layer structure. In one or more embodiments, the substrate 101 may include an organic layer (e.g., a resin-based material) and an inorganic layer, or, for example, may have a structure in which an inorganic layer is arranged between two organic layers.

In one or more embodiments, one or more insulating (e.g., electrically insulating) layers may be arranged on the substrate 101.

In one or more embodiments, one or more thin-film transistors may also be arranged on the substrate 101.

The first electrode 110 may be arranged on the substrate 101. In one or more embodiments, one or more insulating (e.g., electrically insulating) layers may be arranged on the substrate 101, and in this case, the one or more insulating layers may be arranged between the first electrode 110 and the substrate 101.

Further, in one or more embodiments, one or more thin-film transistors may be arranged on the substrate 101, and in this case, the one or more thin-film transistors may be arranged between the first electrode 110 and the substrate 101.

The first electrode 110 may have one or more suitable shapes, for example, the first electrode 110 may be patterned and formed in the shape of an island.

The first electrode 110 may contain one or more suitable conductive (e.g., electrically conductive) materials. As an example, the first electrode 110 may include at least one selected from the group consisting of transparent (e.g., substantially transparent) conductive (e.g., electrically conductive) oxides, such as indium tin oxide (ITO), indium zinc oxide (IZO), zinc oxide (e.g., ZnOₓ, wherein 0<x≤2; e.g., ZnO), indium oxide (e.g., In₂O₃), indium gallium oxide (IGO), and aluminum zinc oxide (AZO). In one or more embodiments, the first electrode 110 may include a highly reflective metal, such as silver (Ag).

In one or more embodiments, the first electrode 110 may include a first region 110A1 having a first height h1 with respect to an upper surface of the substrate 101 and second regions 110A2, each of the second regions 110A2 having a second height h2 with respect to the upper surface of the substrate 101.

In one or more embodiments, the second height h2 may have a smaller value than (e.g., may be lower than) the first height h1. In one or more embodiments, it may be seen that the first region 110A1 has a shape that is formed higher or protrudes more than the second region 110A2 with respect to the upper surface of the substrate 101.

In one or more embodiments, the first electrode 110 may include a third region 110A3 having a third height h3 with respect to the upper surface of the substrate 101, and the third height h3 of the third region 110A3 may have a smaller value than (e.g., may be lower than) the second height h2 of the second region 110A2.

The first region 110A1 of the first electrode 110 may be arranged between the second regions 110A2, which are arranged on at least opposite sides of the first region 110A1 of the first electrode 110 (e.g., between two of the second regions 110A2 that are opposite to each other). In one or more embodiments, the first region 110A1 may be surrounded by the second regions 110A2. For example, the first region 110A1 may be arranged in a region including a central portion of a pixel region defined by an opening of the pixel defining film 180. The second regions 110A2 may be spaced and/or apart (e.g., spaced apart or separated) from the first region 110A1 and may be around (e.g., surround) the first region 110A1.

The third region 110A3 of the first electrode 110 may be arranged adjacent to the first region 110A1 or the second region 110A2. In one or more embodiments, the third region 110A3 may be arranged between the first region 110A1 and the second region 110A2.

In one or more embodiments, the third region 110A3 may be adjacent to the second region 110A2 and may be arranged adjacent to a side surface of the second region 110A2 that is opposite to a side surface opposite to (e.g., facing) the first region 110A1.

In one or more embodiments, the third region 110A3 may be formed or arranged in a region in which the first region 110A1 or the second region 110A2 is not formed.

The structure in which the first electrode 110 is arranged on the substrate 101 will be described herein in more detail.

The first electrode 110 may include a base layer 110a, a first pattern layer 111, and a second pattern layer 112.

The base layer 110a may correspond to the entire (e.g., substantially entire) region of the first electrode 110, and, for example, may correspond to the first region 110A1, the second region 110A2, and the third region 110A3.

The first pattern layer 111 may be formed or arranged on the base layer 110a, for example, to be in contact with an upper surface of the base layer 110a, with a (e.g., set or predetermined) thickness.

The second pattern layer 112 may be formed or arranged on the base layer 110a, for example, to be in contact with the upper surface of the base layer 110a, with a thickness that is at least less than a thickness of the first pattern layer 111.

The first pattern layer 111 and the second pattern layer 112 may be spaced and/or apart (e.g., spaced apart or separated) from each other, for example, with a separation space SA therebetween.

The base layer 110a may be formed or composed of a material different from a material of the first pattern layer 111 and the second pattern layer 112 so as to be distinguished therefrom, and the first pattern layer 111 and the second pattern layer 112 may be formed or composed of substantially the same material.

In one or more embodiments, the base layer 110a may be formed or composed of substantially the same material as the first pattern layer 111 and the second pattern layer 112.

In one or more embodiments, the first region 110A1 of the first electrode 110 may correspond to the base layer 110a and the first pattern layer 111, the second region 110A2 of the first electrode 110 may correspond to the base layer 110a and the second pattern layer 112, and the third region 110A3 of the first electrode 110 may correspond to the region in which the base layer 110a is present.

By allowing the first electrode 110 to include the base layer 110a, the first pattern layer 111, and the second pattern layer 112, the first region 110A1, the second region 110A2, and the third region 110A3, which are the regions of different heights, may be easily or suitably implemented. In one or more embodiments, through this structure of the first electrode 110, differential resonance structures may be implemented within the pixel, thereby improving or enhancing light efficiency.

The second electrode 130 may be opposite to (e.g., face) the first electrode 110. The second electrode 130 may be formed or composed of one or more suitable conductive (e.g., electrically conductive) materials. In one or more embodiments, the second electrode 130 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 120 may include an organic light-emitting layer and may be arranged between the first electrode 110 and the second electrode 130. A low-molecular-weight organic material and/or a high-molecular-weight organic material may be utilized for the organic light-emitting layer of the intermediate layer 120. In one or more embodiments, the intermediate layer 120 may further include at least one selected from the group consisting of a hole injection layer, a hole transport layer, an electron transport layer, and an electron injection layer, in addition to the organic light-emitting layer.

After the pixel defining film 180 is arranged so as not to cover a set or predetermined region of the first electrode 110, the intermediate layer 120 may be arranged on the region of the first electrode 110 that is not covered by the pixel defining film 180, and the second electrode 130 may be arranged on the intermediate layer 120.

The pixel defining film 180 may be formed or composed of one or more suitable insulating (e.g., electrically insulating) materials. In one or more embodiments, the pixel defining film 180 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 180 may include a material that reduces or blocks the reflection of light incident from the outside, and, for example, may include a black organic material, a dark-colored organic material, and/or a black pigment.

In one or more embodiments, one or more encapsulation members or films covering the second electrode 130 may be formed or arranged on the second electrode 130.

In one or more embodiments, the shape of an upper surface of the first electrode 110 may be at least partially implemented in the intermediate layer 120 and the second electrode 130. In one or more embodiments, among the regions of the second electrode 130, the region corresponding to the first pattern layer 111 of the first electrode 110 may have a shape protruded upward, and the region corresponding to the second pattern layer 112 of the first electrode 110 may have a shape protruded upward less than the region corresponding to the first pattern layer 111.

The display apparatus 100 of the present disclosure may have a plurality of regions in the first electrode 110, each with a different height. In one or more embodiments, in descending order of size, the display apparatus 100 may include the first region 110A1 with the first height h1, the second region 110A2 with the second height h2, and the third region 110A3 with the third height h3.

Through these height differences, in the regions corresponding to the first electrode 110, it may be feasible to improve or enhance light efficiency by introducing variations in optical resonance between the first electrode 110 and the second electrode 130 in each region.

As an example, among the regions of the first electrode 110, the region including the center of the region from which light is reflected and extracted forward may be formed with the highest first height h1, allowing the light to be reflected and extracted at a larger angle toward a side surface, and the region farther away from the center of the region from which the light is extracted forward may be formed with the second height h2, which is lower than the first height h1, allowing the light to be reflected and extracted at a smaller angle toward the side surface.

Furthermore, among the regions of the first electrode 110 from which light is reflected and extracted forward, the region adjacent to the edge may be formed with the lowest third height h3, as the first pattern layer 111 and the second pattern layer 112 are not present.

Accordingly, the efficiency of light reflected by the first electrode 110 and extracted may be improved or enhanced. In one or more embodiments, assuming that the structure in FIG. 1 represents a sub-pixel (or pixel), the light reflected from the first electrode 110 may be less likely to be blocked (or a degree or occurrence of the light reflected from the first electrode 110 may be less likely to be reduced) by a light-limiting member on the side surface, and, for example, the pixel defining film 180 or a light-blocking member that may be additionally arranged, thereby improving or enhancing light extraction efficiency along with the light efficiency effect achieved through the optical resonance of the first electrode 110. As a result, the display apparatus 100 may be implemented with improved or enhanced image quality characteristics.

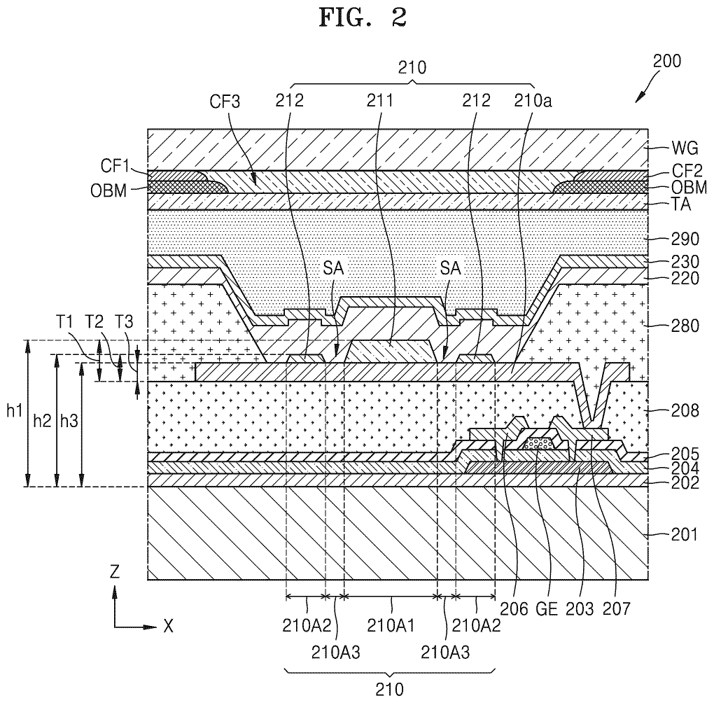

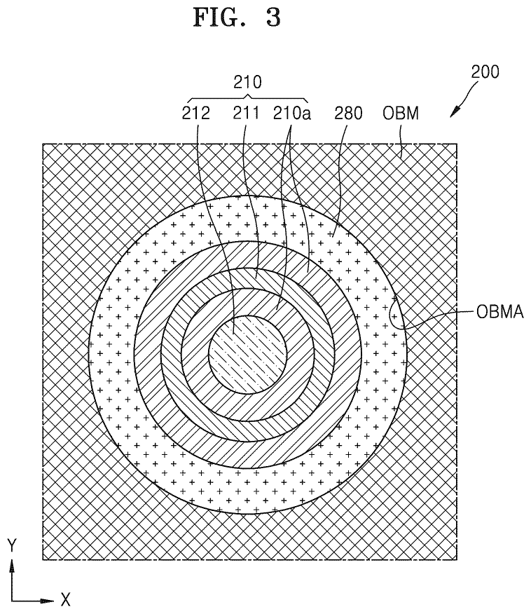

FIG. 2 is a cross-sectional view schematically illustrating a display apparatus according to one or more embodiments of the present disclosure. FIG. 3 is a schematic plan view of FIG. 2, viewed from one direction. In one or more embodiments, FIG. 3 is a plan view of FIG. 2 viewed from above a cover member WG.

Referring to FIGS. 2 and 3, a display apparatus 200 may include a substrate 201, a first electrode 210, a second electrode 230, and an intermediate layer 220.

In one or more embodiments, the display apparatus 200 may further include one or more thin-film transistors, a pixel defining film 280, and/or the like arranged on the substrate 201.

For convenience of description, differences from the foregoing embodiments will be mainly or predominantly described herein in more detail.

The substrate 201 may include one or more suitable materials. In more detail, the substrate 201 may be formed or composed of glass, metal, an organic material, and/or other suitable materials, and the details thereof may be modified and applied within a range that is substantially the same or similar to the substrate 101 as described in one or more embodiments, and thus, more detailed descriptions thereof may not be provided.

In one or more embodiments, one or more buffer layers 202 may be arranged on the substrate 201.

The buffer layers 202 may be arranged on the substrate 201. The buffer layers 202 may reduce or prevent the diffusion of impurities into the thin-film transistor arranged thereabove.

The buffer layer 202 may contain one or more suitable materials, for example, inorganic materials. For example, the buffer layer 202 may contain a silicon-based material. In one or more embodiments, the buffer layer 202 may include at least one selected from among silicon nitride (e.g., SiNₓ, wherein 0<x≤2; e.g., Si₃N₄), silicon oxide (e.g., SiO_{X}, wherein 0<x≤2; e.g., SiO₂), and silicon oxynitride (e.g., SiOₓN_{y}, wherein 0<x≤2 and 0≤y≤2; e.g., SiON or Si₂N₂O).

As another example, the buffer layer 202 may contain an oxide, and, for example, may include at least one of metal oxides, such as aluminum oxide (e.g., AlOₓ, wherein 0<x≤2; e.g., Al₂O₃).

In one or more embodiments, the buffer layer 202 may include a multi-layer of at least two layers or more.

A thin-film transistor may be arranged on the buffer layer 202 and may function as part of a circuit that enables visible light to be emitted from the intermediate layer 220.

Hereinafter, a case is illustrated in which the thin-film transistor may be of the top-gate type (kind), with an active layer 203, a gate electrode GE, a source electrode 206, and a drain electrode 207 that are formed or arranged sequentially.

However, embodiments of the present disclosure are not limited thereto, and one or more suitable types (kinds) of thin-film transistors, such as a bottom gate type (kind), may be employed.

The active layer 203 may be formed or arranged on the buffer layer 202. The active layer 203 may include a semiconductor material and may include, for example, amorphous (e.g., non-crystalline) silicon and/or polycrystalline silicon. However, embodiments of the present disclosure are not limited thereto, and the active layer 203 may include one or more suitable materials. In one or more embodiments, the active layer 203 may contain an organic semiconductor material.

In one or more embodiments, the active layer 203 may contain an oxide semiconductor material. In one or more embodiments, the active layer 203 may include an oxide of a material selected from among the Group 12, 13, or 14 metal elements, such as zinc (Zn), indium (In), gallium (Ga), tin (Sn), cadmium (Cd), germanium (Ge), or hafnium (Hf), and a (e.g., any suitable) combination thereof.

A gate insulating layer 204 may be formed or arranged on the active layer 203. The gate insulating layer 204 may be formed or arranged as a single layer or a multilayer of a film made of inorganic materials, such as silicon oxide and/or silicon nitride. The gate insulating layer 204 may serve to insulate (e.g., to electrically insulate) the active layer 203 from the gate electrode GE.

The gate electrode GE may be formed or arranged above (e.g., on) the gate insulating layer 204. The gate electrode GE may be connected to a gate line that is to transmit one or more electrical signals.

The gate electrode GE may be made of a low-resistance (e.g., electrical resistance) metal material and may be formed or arranged as a single layer or a multilayer of a film made of conductive (e.g., electrically conductive) materials including, for example, molybdenum (Mo), aluminum (Al), copper (Cu), titanium (Ti), and/or the like.

An interlayer insulating film 205 may be formed or arranged on the gate electrode GE. The interlayer insulating film 205 may be to insulate (e.g., to electrically insulate) the source electrode 206 and the drain electrode 207 from the gate electrode GE.

The interlayer insulating film 205 may be formed or arranged as a single layer or a multilayer of a film made of an inorganic material. In one or more embodiments, the inorganic material may be a metal oxide and/or a metal nitride. In one or more embodiments, the inorganic material may include silicon oxide (e.g., SiO_{X}, wherein 0<x≤2; e.g., SiO₂), silicon nitride (e.g., SiNₓ, wherein 0<x≤2; e.g., Si₃N₄), silicon oxynitride (e.g., SiOₓN_{y}, wherein 0<x≤2 and 0≤y≤2; e.g., SiON or Si₂N₂O), aluminum oxide (e.g., AlOₓ, wherein 0<x≤2; e.g., Al₂O₃), titanium oxide (e.g., TiOₓ, wherein 0<x≤2; e.g., TiO₂), tantalum oxide (e.g., TaOₓ, wherein 0<x≤3; e.g., Ta₂O₅), hafnium oxide (e.g., HfO₂), zirconium oxide (ZrO₂), and/or the like.

The source electrode 206 and the drain electrode 207 may be formed or arranged on the interlayer insulating film 205. The source electrode 206 and the drain electrode 207 may be formed or arranged as a single layer or a multilayer using a highly conductive (e.g., electrically conductive) material.

The source electrode 206 and the drain electrode 207 may be in contact with a region of the active layer 203.

A passivation film 208 may cover the thin-film transistor, for example, over the source electrode 206 and the drain electrode 207.

The passivation film 208 may be to planarize an upper surface of the thin-film transistor by eliminating a step difference caused by the thin-film transistor, thereby reducing or preventing display performance defects (e.g., a degree or occurrence of display performance defects) in the display apparatus 200 that may arise from underlying irregularities.

The passivation film 208 may include an insulating (e.g., electrically insulating) material and may include a single layer or a multilayer of a film containing, for example, an organic material.

As an example, the passivation film 208 may include organic materials, such as general-purpose polymers, e.g., polymethylmethacrylate (PMMA) and/or polystyrene (PS), polymer derivatives with phenolic groups, acrylic polymers, imide polymers, aryl ether polymers, amide polymers, fluorinated polymers, p-xylene polymers, vinyl alcohol polymers, and any suitable blends thereof. In one or more embodiments, the passivation film 208 may be formed or arranged as a composite laminate of an inorganic insulating (e.g., electrically insulating) film and an organic insulating (e.g., electrically insulating) film.

The first electrode 210 may be arranged on the passivation film 208. The first electrode 210 may be electrically connected to one selected from the source electrode 206 and the drain electrode 207.

The first electrode 210 may contain one or more suitable conductive (e.g., electrically conductive) materials (e.g., electron conductors), and the materials of the first electrode 210 may be substantially the same as the materials of the first electrode 110 as described in one or more embodiments, and thus, a more detailed description thereof may not be provided herein.

In one or more embodiments, the first electrode 210 may include a first region 210A1 having a first height h1 with respect to an upper surface of the substrate 201, and second regions 210A2, each of the second regions 210A2 having a second height h2 with respect to the upper surface of the substrate 201.

In one or more embodiments, the second height h2 may have a smaller value than (e.g., may be lower than) the first height h1. In one or more embodiments, it may be seen that the first region 210A1 has a shape that is formed higher or protrudes more than the second region 210A2 with respect to the upper surface of the substrate 201.

In one or more embodiments, the first electrode 210 may include a third region 210A3 having a third height h3 with respect to the upper surface of the substrate 201, and the third height h3 of the third region 210A3 may have a smaller value than (e.g., may be lower than) the second height h2 of the second region 210A2.

The first region 210A1 of the first electrode 210 may be arranged between the second regions 210A2, which are arranged on at least opposite sides of the first region 210A1 of the first electrode 210 (e.g., between two of the second regions 210A2 that are opposite to each other). In one or more embodiments, the first region 210A1 may be surrounded by the second regions 210A2. For example, the first region 210A1 may be arranged in a region including a central portion of a region defined by an opening of the pixel defining film 280 or a central portion of a region defined by an opening OBMA of a light-blocking member OBM to be described herein in more detail. The second regions 210A2 may be spaced and/or apart (e.g., spaced apart or separated) from the first region 210A1 and may be around (e.g., surround) the first region 210A1.

The third region 210A3 of the first electrode 210 may be adjacent to the first region 210A1 or the second region 210A2. In one or more embodiments, the third region 210A3 may be between the first region 210A1 and the second region 210A2.

In one or more embodiments, as another example, the third region 210A3 may be adjacent to the second region 210A2 and may be adjacent to a side surface of the second region 210A2 that is opposite to a side surface opposite to (e.g., facing) the first region 210A1.

In one or more embodiments, the third region 210A3 may be formed or arranged in a region in which the first region 210A1 or the second region 210A2 is not formed.

The structure in which the first electrode 210 is arranged on the substrate 201 will be described herein in more detail.

The first electrode 210 may include a base layer 210a, a first pattern layer 211, and a second pattern layer 212.

The base layer 210a may be electrically connected to one selected from the source electrode 206 and the drain electrode 207, and, for example, may be in contact therewith.

The base layer 210a may correspond to the entire (e.g., substantially entire) region of the first electrode 210, and, for example, may correspond to the first region 210A1, the second region 210A2, and the third region 210A3.

The first pattern layer 211 may be formed or arranged on the base layer 210a, for example, to be in contact with an upper surface of the base layer 210a, with a (e.g., set or predetermined) thickness.

The second pattern layer 212 may be formed or arranged on the base layer 210a, for example, to be in contact with the upper surface of the base layer 210a, with a thickness that is at least less than a thickness of the first pattern layer 211.

In one or more embodiments, the base layer 210a may have a thickness T3, which may correspond to the thickness of the third region 210A3. A total thickness T1 of the base layer 210a and the first pattern layer 211 may correspond to the thickness of the first region 210A1. A total thickness T2 of the base layer 210a and the second pattern layer 212 may correspond to the thickness of the second region 210A2.

In one or more embodiments, values of the thickness T1, the thickness T2, and the thickness T3 may be sequential in size, and, for example, the thickness T1 may be the largest, followed by the thickness T2, with the thickness T3 being the smallest.

By controlling these thicknesses, the first electrode 210 may have different heights in each region.

The first pattern layer 211 and the second pattern layer 212 may be spaced and/or apart (e.g., spaced apart or separated) from each other, for example, with a separation space SA therebetween.

The base layer 210a may be formed or composed of a material different from a material of the first pattern layer 211 and the second pattern layer 212 so as to be distinguished therefrom, and the first pattern layer 211 and the second pattern layer 212 may be formed or composed of substantially the same material.

In one or more embodiments, the base layer 210a may be formed or composed of substantially the same material as the first pattern layer 211 and the second pattern layer 212.

In one or more embodiments, the first region 210A1 of the first electrode 210 may correspond to the base layer 210a and the first pattern layer 211, the second region 210A2 of the first electrode 210 may correspond to the base layer 210a and the second pattern layer 212, and the third region 210A3 of the first electrode 210 may correspond to the region in which the base layer 210a is present.

By allowing the first electrode 210 to include the base layer 210a, the first pattern layer 211, and the second pattern layer 212, the first region 210A1, the second region 210A2, and the third region 210A3, which are the regions of different heights, may be easily or suitably implemented. In one or more embodiments, through this structure of the first electrode 210, differential resonance structures may be implemented within the pixel, thereby improving or enhancing light efficiency.

The second electrode 230 may be opposite to (e.g., face) the first electrode 210. The second electrode 230 may be formed or composed of one or more suitable conductive (e.g., electrically conductive) materials. In one or more embodiments, the second electrode 230 may contain lithium (Li), calcium (Ca), lithium fluoride (LiF), aluminum (Al), magnesium (Mg), and/or silver (Ag), may be formed or arranged as a single layer or a multilayer of at least one selected among the foregoing materials, and may include an alloy material containing at least two selected from among the foregoing materials.

The intermediate layer 220 may include an organic light-emitting layer and may be arranged between the first electrode 210 and the second electrode 230. A low-molecular-weight organic material and/or a high-molecular-weight organic material may be utilized for the organic light-emitting layer of the intermediate layer 220. In one or more embodiments, the intermediate layer 220 may further include at least one selected from the group consisting of a hole injection layer, a hole transport layer, an electron transport layer, and an electron injection layer, in addition to the organic light-emitting layer.

After the pixel defining film 280 is arranged so as not to cover a set or predetermined region of the first electrode 210, the intermediate layer 220 may be arranged on the region of the first electrode 210 that is not covered by the pixel defining film 280, and the second electrode 230 may be arranged on the intermediate layer 220.

The pixel defining film 280 may be formed or composed of one or more suitable insulating (e.g., electrically insulating) materials. In one or more embodiments, the pixel defining film 280 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 280 may include a material that reduces or blocks the reflection of light incident from the outside, and, for example, may include a black organic material, a dark-colored organic material, and/or a black pigment.

An encapsulation portion 290 may be arranged above (e.g., on) the second electrode 230. As an example, the encapsulation portion 290 may include one or a plurality of encapsulation layers. In one or more embodiments, the encapsulation portion 290 may include one or more inorganic layers or one or more organic layers. As an example, the encapsulation portion 290 may have a structure in which inorganic layers and organic layers are alternately stacked at least once, and, for example, a structure in which inorganic layers and organic layers are alternately stacked two or more times.

In one or more embodiments, the light-blocking member OBM may further be arranged above (e.g., on) the encapsulation portion 290. The light-blocking member OBM may include opening region OBMA that allows light generated from below, such as light generated by the intermediate layer 220 or light reflected by the first electrode 210 and extracted, to pass therethrough. The light-blocking member OBM may be a black matrix (BM) that blocks light (or reduces a degree or occurrence of light).

In one or more embodiments, referring to FIG. 3, the opening region OBMA of the light-blocking member OBM may include a curved edge, such as a circular (e.g., substantially circular) edge. In one or more embodiments, an edge of the first electrode 210 may have a similarly curved or circular (e.g., substantially circular) shape to correspond to the edge of the opening region OBMA.

FIG. 3 is a schematic plan view of FIG. 2 viewed from one direction and illustrates only the light-blocking member OBM, the pixel defining film 280, and the first electrode 210 for convenience of description.

The first pattern layer 211 of the first electrode 210 may be arranged in a region including a central region of the opening region OBMA, and the second pattern layer 212 may be spaced and/or apart (e.g., spaced apart or separated) from and may be around (e.g., surround) the first pattern layer 211. In one or more embodiments, the second pattern layer 212 may be spaced and/or apart (e.g., spaced apart or separated) from a boundary line of the opening region OBMA.

In one or more embodiments, the base layer 210a may be arranged in a gap between the first pattern layer 211 and the second pattern layer 212 and in a space between the second pattern layer 212 and the boundary line of the opening region OBMA.

In one or more embodiments, these regions of the first pattern layer 211, the second pattern layer 212, and the base layer 210a as illustrated in FIG. 3 may correspond to the first region 210A1, the second region 210A2, and the third region 210A3 of the first electrode 210, respectively.

In one or more embodiments, the boundary line of the opening region OBMA may include a straight line, and, for example, the opening region OBMA may have a polygonal shape (e.g., a substantially polygonal shape). In that case, the boundary line or edge of the first electrode 210 may include a straight line and may have a polygonal shape (e.g., a substantially polygonal shape).

In one or more embodiments, color filter layers CF1, CF2, and CF3 may be located or arranged above (e.g., on) the opening region OBMA of the light-blocking member OBM and a portion of the light-blocking member OBM. Each of the color filter layers CF1, CF2, and CF3 may have a different color.

In one or more embodiments, the cover member WG may be located or arranged above (e.g., on) the light-blocking member OBM and the color filter layers CF1, CF2, and CF3, and the cover member WG may include a glass material.

In one or more embodiments, the display apparatus 200 may include one or more touch pattern layers TA, such as one or more conductive (e.g., electrically conductive) patterns. The touch pattern layers TA may be formed or arranged on an upper surface of the encapsulation portion 290, or, in one or more embodiments, on a lower or upper surface of the cover member WG.

In one or more embodiments, the shape of an upper surface of the first electrode 210 may be at least partially implemented in the intermediate layer 220 and the second electrode 230. In one or more embodiments, among the regions of the second electrode 230, the region corresponding to the first pattern layer 211 of the first electrode 210 may have a shape protruded upward, and the region corresponding to the second pattern layer 212 of the first electrode 210 may have a shape protruded upward less than the region corresponding to the first pattern layer 211.

The display apparatus 200 of one or more embodiments of the present disclosure may have a plurality of regions in the first electrode 210, each with a different height. In one or more embodiments, in descending order of size, the display apparatus 200 may include the first region 210A1 with the first height h1, the second region 210A2 with the second height h2, and the third region 210A3 with the third height h3.

Through these height differences, in the regions corresponding to the first electrode 210, it may be feasible to improve or enhance light efficiency by introducing variations in optical resonance between the first electrode 210 and the second electrode 230 in each region.

As an example, among the regions of the first electrode 210, the region including the center of the region from which light is reflected and extracted forward, for example, the region including the center of the opening region OBMA of the light-blocking member OBM, may be formed with the highest first height h1, allowing the light to be reflected and extracted at a larger angle toward a side surface, and the region farther away from the center of the region from which the light is extracted forward, for example, the region farther away from the center of the opening region OBMA of the light-blocking member OBM, may be formed with the second height h2, which is lower than the first height h1, allowing the light to be reflected and extracted at a smaller angle toward the side surface.

Furthermore, among the regions of the first electrode 210 from which light is reflected and extracted forward, the region adjacent to the edge, for example, the region adjacent to the boundary line of the opening region OBMA of the light-blocking member OBM may be formed with the lowest third height h3, as the first pattern layer 211 and the second pattern layer 212 are not present.

Accordingly, the efficiency of light reflected by the first electrode 210 and extracted may be improved or enhanced. In one or more embodiments, by reducing or preventing the light reflected by the first electrode 210 and extracted from being blocked by the light-blocking member OBM, the light extraction efficiency may be improved or enhanced along with the effect of light efficiency through the optical resonance of the first electrode 210. As a result, the display apparatus 200 may be implemented with improved or enhanced image quality characteristics.

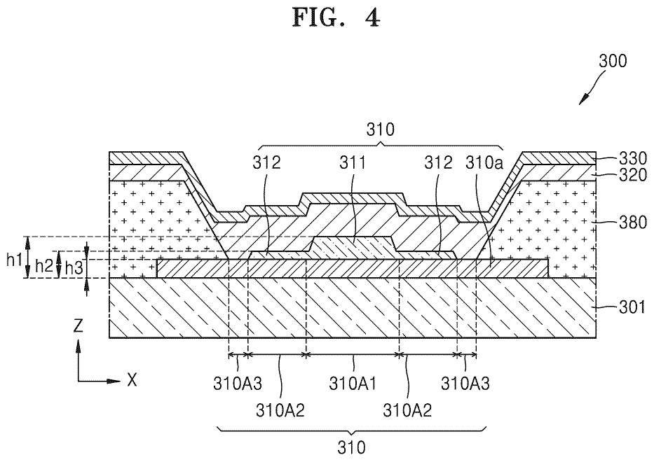

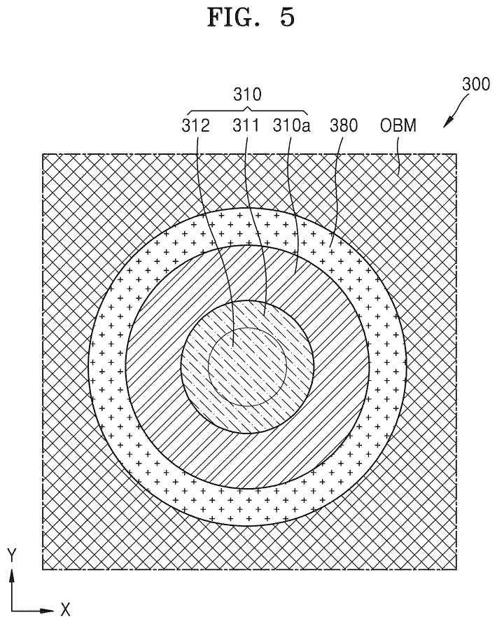

FIG. 4 is a cross-sectional view schematically illustrating a display apparatus according to one or more embodiments of the present disclosure. FIG. 5 is a schematic plan view of FIG. 4, viewed from one direction. In one or more embodiments, FIG. 5 is a plan view of FIG. 4 viewed from above a second electrode 330.

Referring to FIGS. 4 and 5, a display apparatus 300 may include a substrate 301, a first electrode 310, the second electrode 330, and an intermediate layer 320.

In one or more embodiments, the display apparatus 300 may further include one or more thin-film transistors, a pixel defining film 380, and/or the like arranged on the substrate 301.

For convenience of description, differences from the foregoing embodiments will be mainly or predominantly described herein in more detail.

The substrate 301 may include one or more suitable materials. In more detail, the substrate 301 may be formed or composed of glass, metal, an organic material, and/or other suitable materials, and the details thereof may be modified and applied within a range that is substantially the same or similar to the substrate 101 as descried in one or more embodiments, and thus, more detailed descriptions thereof may not be provided.

In one or more embodiments, one or more buffer layers may be arranged on the substrate 301, for example, in a manner similar to the buffer layer 202 of FIG. 2, and a detailed description thereof may be substantially the same as provided in FIG. 2.

In one or more embodiments, one or more thin-film transistors may be arranged as illustrated in FIG. 2.

The first electrode 310 may be arranged on the substrate 301. The thin-film transistor may be arranged as described in one or more embodiments, and the first electrode 310 may be arranged above (e.g., on) an insulating (e.g., electrically insulating) layer arranged on the thin-film transistor. The first electrode 310 may contain one or more suitable conductive (e.g., electrically conductive) materials, and the materials of the first electrode 310 may be substantially the same as the materials of the first electrode 310 as described in one or more embodiments, and thus, a more detailed description thereof may not be provided.

In one or more embodiments, the first electrode 310 may include a first region 310A1 having a first height h1 with respect to an upper surface of the substrate 301 and second regions 310A2, each of the second regions 310A2 having a second height h2 with respect to the upper surface of the substrate 301.

In one or more embodiments, the second height h2 may have a smaller value than (e.g., may be lower than) the first height h1. In one or more embodiments, it may be seen that the first region 310A1 has a shape that is formed higher or protrudes more than the second region 310A2 with respect to the upper surface of the substrate 301.

In one or more embodiments, the first electrode 310 may include a third region 310A3 having a third height h3 with respect to the upper surface of the substrate 301, and the third height h3 of the third region 310A3 may have a smaller value than (e.g., may be lower than) the second height h2 of the second region 310A2.

The first region 310A1 of the first electrode 310 may be arranged between the second regions 310A2, which are arranged on at least opposite sides of the first region 310A1 of the first electrode 310 (e.g., between two of the second regions 310A2 that are opposite to each other). In one or more embodiments, the first region 310A1 may be surrounded by the second regions 310A2. For example, the first region 310A1 may be arranged in a region including a central portion of a region defined by an opening of the pixel defining film 380 or a central portion of a region defined by an opening of a light-blocking member. The second region 310A2 may be connected to the first region 310A1 and may be around (e.g., surround) the first region 310A1.

The third region 310A3 of the first electrode 310 may be arranged adjacent to the second region 310A2. In one or more embodiments, the third region 310A3 may be adjacent to the second region 310A2 and may be arranged adjacent to a side surface of the second region 310A2 that is opposite to a side surface opposite to (e.g., facing) the first region 310A1.

In one or more embodiments, the third region 310A3 may be formed or arranged in a region in which the first region 310A1 or the second region 310A2 is not formed.

The structure in which the first electrode 310 is arranged on the substrate 301 will be described herein in more detail.

The first electrode 310 may include a base layer 310a, a first pattern layer 311, and a second pattern layer 312.

The base layer 310a may correspond to the entire (e.g., substantially entire) region of the first electrode 310, and, for example, may correspond to the first region 310A1, the second region 310A2, and the third region 310A3.

The first pattern layer 311 may be formed or arranged on the base layer 310a, for example, to be in contact with an upper surface of the base layer 310a, with a (e.g., set or predetermined) thickness.

The second pattern layer 312 may be formed or arranged on the base layer 310a, for example, to be in contact with the upper surface of the base layer 310a, with a thickness that is at least less than a thickness of the first pattern layer 311.

In one or more embodiments, the base layer 310a may have a thickness, which may correspond to the thickness of the third region 310A3. A total thickness of the base layer 310a and the first pattern layer 311 may correspond to the thickness of the first region 310A1. A total thickness of the base layer 310a and the second pattern layer 312 may correspond to the thickness of the second region 310A2.

By controlling these thicknesses, the first electrode 310 may have different heights in each region.

The first pattern layer 311 and the second pattern layer 312 may be arranged in connection with each other, and, for example, the first pattern layer 311 and the second pattern layer 312 may be laterally connected. For example, the first pattern layer 311 and the second pattern layer 312 may take the form of being integrally connected.

The base layer 310a may be formed or composed of a material different from a material of the first pattern layer 311 and the second pattern layer 312 so as to be distinguished therefrom, and the first pattern layer 311 and the second pattern layer 312 may be formed or composed of substantially the same material.

In one or more embodiments, the base layer 310a may be formed or composed of substantially the same material as the first pattern layer 311 and the second pattern layer 312.

In one or more embodiments, the first region 310A1 of the first electrode 310 may correspond to the base layer 310a and the first pattern layer 311, the second region 310A2 of the first electrode 310 may correspond to the base layer 310a and the second pattern layer 312, and the third region 310A3 of the first electrode 310 may correspond to the region in which the base layer 310a is present.

By allowing the first electrode 310 to include the base layer 310a, the first pattern layer 311, and the second pattern layer 312, the first region 310A1, the second region 310A2, and the third region 310A3, which are the regions of different heights, may be easily or suitably implemented. In one or more embodiments, through this structure of the first electrode 310, differential resonance structures may be implemented within the pixel, thereby improving or enhancing light efficiency.

The second electrode 330 may be opposite to (e.g., face) the first electrode 310. The second electrode 330 may be formed or composed of one or more suitable conductive (e.g., electrically conductive) materials. In one or more embodiments, the second electrode 330 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 320 may include an organic light-emitting layer and may be arranged between the first electrode 310 and the second electrode 330. A low-molecular-weight organic material and/or a high-molecular-weight organic material may be utilized for the organic light-emitting layer of the intermediate layer 320. In one or more embodiments, the intermediate layer 320 may further include at least one selected from the group consisting of a hole injection layer, a hole transport layer, an electron transport layer, and an electron injection layer, in addition to the organic light-emitting layer.

After the pixel defining film 380 is arranged so as not to cover a set or predetermined region of the first electrode 310, the intermediate layer 320 may be arranged on the region of the first electrode 310 that is not covered by the pixel defining film 380, and the second electrode 330 may be arranged on the intermediate layer 320.

The pixel defining film 380 may be formed or composed of one or more suitable insulating (e.g., electrically insulating) materials (e.g., electron insulator. In one or more embodiments, the pixel defining film 380 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 380 may include a material that reduces or blocks the reflection of light incident from the outside, and, for example, may include a black organic material, a dark-colored organic material, and/or a black pigment.

In one or more embodiments, an encapsulation portion may further be arranged, and more details thereof may be substantially the same as illustrated in FIG. 2 of one or more embodiments.

In one or more embodiments, a light-blocking member OBM may be arranged as illustrated in FIG. 5, and referring to FIG. 5, an opening region OBMA of the light-blocking member OBM may include a curved edge, such as a circular (e.g., substantially circular) edge.

The first pattern layer 311 of the first electrode 310 may be arranged in a region including a central region of the opening region OBMA, and the second pattern layer 312 may be around (e.g., surround) and be connected to the first pattern layer 311. In one or more embodiments, the second pattern layer 312 may be spaced and/or apart (e.g., spaced apart or separated) from a boundary line of the opening region OBMA.

The base layer 310a may be arranged between the second pattern layer 312 and the boundary line of the opening region OBMA.

In one or more embodiments, these regions of the first pattern layer 311, the second pattern layer 312, and the base layer 310a as illustrated in FIG. 5 may correspond to the first region 310A1, the second region 310A2, and the third region 310A3 of the first electrode 310, respectively.

In one or more embodiments, a color filter layer may be located or arranged above (e.g., on) the opening region OBMA of the light-blocking member OBM and a portion of the light-blocking member OBM, and this may be substantially the same as described in one or more embodiments of FIG. 2.

In one or more embodiments, a cover member may further be arranged, and the cover member may be substantially the same as described in one or more embodiments of FIG. 2.

In one or more embodiments, the display apparatus 300 may include one or more touch pattern layers, such as one or more conductive (e.g., electrically conductive) patterns, and this may be substantially the same as described herein in one or more embodiments of FIG. 2.

In one or more embodiments, the shape of an upper surface of the first electrode 310 may be at least partially implemented in the intermediate layer 320 and the second electrode 330. In one or more embodiments, among the regions of the second electrode 330, the region corresponding to the first pattern layer 311 of the first electrode 310 may have a shape protruded upward, and the region corresponding to the second pattern layer 312 of the first electrode 310 may have a shape protruded upward less than the region corresponding to the first pattern layer 311.

The display apparatus 300 of the present disclosure may have a plurality of regions in the first electrode 310, each with a different height. In one or more embodiments, in descending order of size, the display apparatus 300 may include the first region 310A1 with the first height h1, the second region 310A2 with the second height h2, and the third region 310A3 with the third height h3.

Through these height differences, in the regions corresponding to the first electrode 310, it may be feasible to improve or enhance light efficiency by introducing variations in optical resonance between the first electrode 310 and the second electrode 330 in each region.

As an example, among the regions of the first electrode 310, the region including the center of the region from which light is reflected and extracted forward, for example, the region including the center of the opening region OBMA of the light-blocking member OBM, may be formed with the highest first height h1, allowing the light to be reflected and extracted at a larger angle toward a side surface, and the region farther away from the center of the region from which the light is extracted forward, for example, the region farther away from the center of the opening region OBMA of the light-blocking member OBM, may be formed with the second height h2, which is lower than the first height h1, allowing the light to be reflected and extracted at a smaller angle toward the side surface.

In one or more embodiments, the first region 310A1 and the second region 310A2 may be connected to each other, and, for example, the first pattern layer 311 and the second pattern layer 312 may be connected or integrally formed. Through this, the difference in optical resonance between adjacent regions of the first electrode 310 may be gradually adjusted, thereby improving or enhancing the uniformity of light efficiency, and a defect rate during the formation of the first electrode 310 may be reduced, thereby securing stable manufacturing characteristics of the first electrode 310.

Furthermore, among the regions of the first electrode 310 from which light is reflected and extracted forward, the region adjacent to the edge, for example, the region adjacent to the boundary line of the opening region OBMA of the light-blocking member OBM may be formed with the lowest third height h3, as the first pattern layer 311 and the second pattern layer 312 are not present.

Accordingly, the efficiency of light reflected by the first electrode 310 and extracted may be improved or enhanced. In one or more embodiments, by reducing or preventing the light reflected by the first electrode 310 and extracted from being blocked by the light-blocking member OBM, the light extraction efficiency may be improved or enhanced along with the effect of light efficiency through the optical resonance of the first electrode 310. As a result, the display apparatus 300 may be implemented with improved or enhanced image quality characteristics.

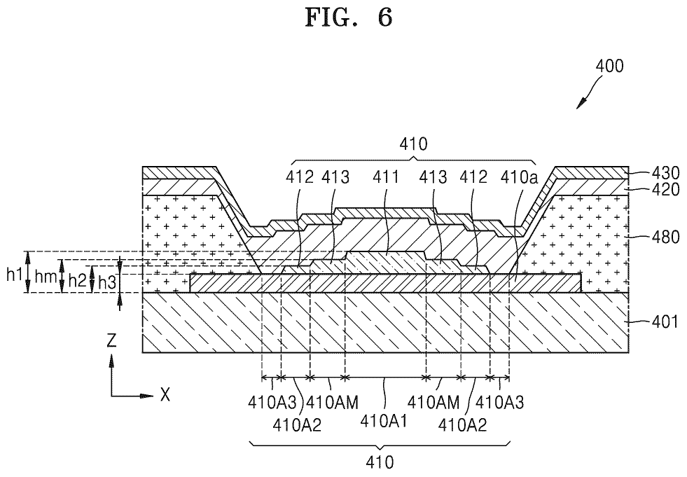

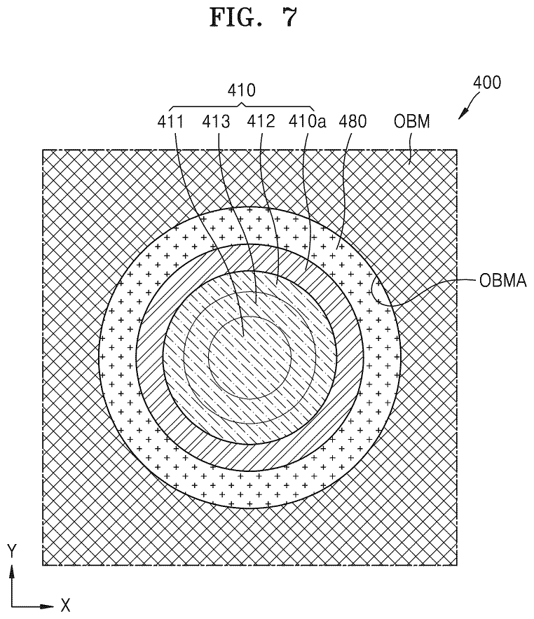

FIG. 6 is a cross-sectional view schematically illustrating a display apparatus according to one or more embodiments of the present disclosure. FIG. 7 is a schematic plan view of FIG. 6, viewed from one direction.

Referring to FIGS. 6 and 7, a display apparatus 400 may include a substrate 401, a first electrode 410, a second electrode 430, and an intermediate layer 420.

In one or more embodiments, the display apparatus 400 may further include one or more thin-film transistors, a pixel defining film 480, and/or the like arranged on the substrate 401.

For convenience of description, differences from the foregoing embodiments will be mainly or predominantly described herein in more detail.

The substrate 401 may include one or more suitable materials. In more detail, the substrate 401 may be formed or composed of glass, metal, an organic material, and/or other suitable materials, and the details thereof may be modified and applied within a range that is substantially the same or similar to the substrate 101 of one or more embodiments, and thus, more detailed descriptions thereof may not be provided.

In one or more embodiments, one or more buffer layers may be arranged on the substrate 401, for example, in a manner similar to the buffer layer 202 of FIG. 2, and a detailed description thereof may be substantially the same as provided in FIG. 2.

In one or more embodiments, one or more thin-film transistors may be arranged as illustrated in FIG. 2.

The first electrode 410 may be arranged on the substrate 401. The thin-film transistor may be arranged as described in one or more embodiments, and the first electrode 410 may be arranged above (e.g., on) an insulating (e.g., electrically insulating) layer arranged on the thin-film transistor. The first electrode 410 may contain one or more suitable conductive (e.g., electrically conductive) materials, and the materials of the first electrode 410 may be substantially the same as the materials of the first electrode 410 in one or more embodiments, and thus, a more detailed description thereof may not be provided.

In one or more embodiments, the first electrode 410 may include a first region 410A1 having a first height h1 with respect to an upper surface of the substrate 401 and second regions 410A2, each of the second regions 410A2 having a second height h2 with respect to the upper surface of the substrate 401.

In one or more embodiments, the second height h2 may have a smaller value than (e.g., may be lower than) the first height h1. In one or more embodiments, it may be seen that the first region 410A1 has a shape that is formed higher or protrudes more than the second region 410A2 with respect to the upper surface of the substrate 401.

In one or more embodiments, the first electrode 410 may include an intermediate region 410AM having an intermediate height hm with respect to the upper surface of the substrate 401.

In this case, the value of the intermediate height hm may be less than the value of the first height h1 and greater than the value of the second height h2.

In one or more embodiments, the first electrode 410 may include a third region 410A3 having a third height h3 with respect to the upper surface of the substrate 401, and the third height h3 of the third region 410A3 may have a smaller value than (e.g., may be lower than) the second height h2 of the second region 410A2.

In one or more embodiments, the third height h3 of the third region 410A3 may have a smaller value than (e.g., may be lower than) the intermediate height hm of the intermediate region 410AM.

The first region 410A1 of the first electrode 410 may be arranged between the second regions 410A2, which are arranged on at least opposite sides of the first region 410A1 of the first electrode 410 (e.g., between two of the second regions 410A2 that are opposite to each other). In one or more embodiments, the first region 410A1 may be surrounded by the second regions 410A2. For example, the first region 410A1 may be arranged in a region including a central portion of a region defined by an opening of the pixel defining film 480 or a central portion of a region defined by an opening of a light-blocking member. The second regions 410A2 may be spaced and/or apart (e.g., spaced apart or separated) from the first region 410A1 and may be around (e.g., surround) the first region 410A1.

The intermediate region 410AM of the first electrode 410 may be arranged between the first region 410A1 and the second region 410A2. In one or more embodiments, the intermediate region 410AM may be around (e.g., surround) the first region 410A1, and the intermediate region 410AM may be surrounded by the second regions 410A2.

In FIG. 6, the intermediate region 410AM is illustrated as having a single region, but in one or more embodiments, the intermediate region 410AM may have two or more regions of different heights, thereby implementing a gradual change in height from the first region 410A1 to the second region 410A2.

The third region 410A3 of the first electrode 410 may be arranged adjacent to the second region 410A2. In one or more embodiments, the third region 410A3 may be adjacent to the second region 410A2 and may be arranged adjacent to a side surface of the second region 410A2 that is opposite to a side surface opposite to (e.g., facing) the first region 410A1.

In one or more embodiments, the third region 410A3 may be formed or arranged in a region in which the first region 410A1 or the second region 410A2 is not formed.

The structure in which the first electrode 410 is arranged on the substrate 401 will be described herein in more detail.

The first electrode 410 may include a base layer 410a, a first pattern layer 411, a second pattern layer 412, and an intermediate pattern layer 413.

The base layer 410a may correspond to the entire (e.g., substantially entire) region of the first electrode 410, and, for example, may correspond to the first region 410A1, the second region 410A2, the intermediate region 410AM, and the third region 410A3.

The first pattern layer 411 may be formed or arranged on the base layer 410a, for example, to be in contact with an upper surface of the base layer 410a, with a (e.g., set or predetermined) thickness.

The second pattern layer 412 may be formed or arranged on the base layer 410a, for example, to be in contact with the upper surface of the base layer 410a, with a thickness that is at least less than a thickness of the first pattern layer 411.

In one or more embodiments, the base layer 410a may have a thickness, which may correspond to the thickness of the third region 410A3. A total thickness of the base layer 410a and the first pattern layer 411 may correspond to the thickness of the first region 410A1. A total thickness of the base layer 410a and the second pattern layer 412 may correspond to the thickness of the second region 410A2. A total thickness of the base layer 410a and the intermediate pattern layer 413 may correspond to the thickness of the intermediate region 410AM.

By controlling these thicknesses, the first electrode 410 may have different heights in each region.

The first pattern layer 411 and the second pattern layer 412 may be arranged spaced and/or apart (e.g., spaced apart or separated) from each other, and the intermediate pattern layer 413 may be arranged between the first pattern layer 411 and the second pattern layer 412.

The intermediate pattern layer 413 may be connected to either the first pattern layer 411 or the second pattern layer 412, and, for example, the intermediate pattern layer 413 may be formed or arranged integrally connected to both (e.g., simultaneously) the first pattern layer 411 and the second pattern layer 412.

The base layer 410a may be formed or composed of a material different from a material of the first pattern layer 411, the second pattern layer 412, and the intermediate pattern layer 413 so as to be distinguished therefrom, and the first pattern layer 411, the second pattern layer 412, and the intermediate pattern layer 413 may be formed or composed of substantially the same material.

In one or more embodiments, the base layer 410a may be formed or composed of substantially the same material as the first pattern layer 411, the second pattern layer 412, and the intermediate pattern layer 413.

In one or more embodiments, the first region 410A1 of the first electrode 410 may correspond to the base layer 410a and the first pattern layer 411, the second region 410A2 of the first electrode 410 may correspond to the base layer 410a and the second pattern layer 412, the intermediate region 410AM of the first electrode 410 may correspond to the base layer 410a and the intermediate pattern layer 413, and the third region 410A3 of the first electrode 410 may correspond to the region in which the base layer 410a is present.

By allowing the first electrode 410 to include the base layer 410a, the first pattern layer 411, the second pattern layer 412, and the intermediate pattern layer 413, the first region 410A1, the second region 410A2, the intermediate region 410AM, and the third region 410A3, which are the regions of different heights, may be easily or suitably implemented. In one or more embodiments, through this structure of the first electrode 410, differential resonance structures may be implemented within the pixel, thereby improving or enhancing light efficiency.

The second electrode 430 may be opposite to (e.g., face) the first electrode 410. The second electrode 430 may be formed or composed of one or more suitable conductive (e.g., electrically conductive) materials. In one or more embodiments, the second electrode 430 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 420 may include an organic light-emitting layer and may be arranged between the first electrode 410 and the second electrode 430. A low-molecular-weight organic material and/or a high-molecular-weight organic material may be utilized for the organic light-emitting layer of the intermediate layer 420. In one or more embodiments, the intermediate layer 420 may further include at least one selected from the group consisting of a hole injection layer, a hole transport layer, an electron transport layer, and an electron injection layer, in addition to the organic light-emitting layer.

After the pixel defining film 480 is arranged so as not to cover a set or predetermined region of the first electrode 410, the intermediate layer 420 may be arranged on the region of the first electrode 410 that is not covered by the pixel defining film 480, and the second electrode 430 may be arranged on the intermediate layer 420.

The pixel defining film 480 may be formed or composed of one or more suitable insulating (e.g., electrically insulating) materials. In one or more embodiments, the pixel defining film 480 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 480 may include a material that reduces or blocks the reflection of light incident from the outside, and, for example, may include a black organic material, a dark-colored organic material, and/or a black pigment.

In one or more embodiments, an encapsulation portion may further be arranged, and details thereof may be substantially the same as illustrated in FIG. 2 of one or more embodiments.

In one or more embodiments, a light-blocking member OBM may be arranged as illustrated in FIG. 7, and referring to FIG. 7, an opening region OBMA of the light-blocking member OBM may include a curved edge, such as a circular (e.g., substantially circular) edge.

The first pattern layer 411 of the first electrode 410 may be arranged in a region including a central region of the opening region OBMA, the intermediate pattern layer 413 may be around (e.g., surround) and be connected to the first pattern layer 411, and the second pattern layer 412 may be connected to the intermediate pattern layer 413. In one or more embodiments, the second pattern layer 412 may be spaced and/or apart (e.g., spaced apart or separated) from a boundary line of the opening region OBMA.

The base layer 410a may be arranged between the second pattern layer 412 and the boundary line of the opening region OBMA.

In one or more embodiments, the regions of the first pattern layer 411, the intermediate pattern layer 413, the second pattern layer 412, and the base layer 410a as illustrated in FIG. 7 may correspond to the first region 410A1, the intermediate region 410AM, the second region 410A2, and the third region 410A3 of the first electrode 410, respectively.

In one or more embodiments, a color filter layer may be located or arranged above (e.g., on) the opening region OBMA of the light-blocking member OBM and a portion of the light-blocking member OBM, and this may be substantially the same as described in one or more embodiments of FIG. 2.

In one or more embodiments, a cover member may further be arranged, and the cover member may be substantially the same as described in one or more embodiments of FIG. 2.

In one or more embodiments, the display apparatus 400 may include one or more touch pattern layers, such as one or more conductive (e.g., electrically conductive) patterns, and this may be substantially the same as described in one or more embodiments of FIG. 2.

In one or more embodiments, the shape of an upper surface of the first electrode 410 may be at least partially implemented in the intermediate layer 420 and the second electrode 430. In one or more embodiments, among the regions of the second electrode 430, the region corresponding to the first pattern layer 411 of the first electrode 410 may have a shape protruded upward, and the region corresponding to the second pattern layer 412 of the first electrode 410 may have a shape protruded upward less than the region corresponding to the first pattern layer 411.

The display apparatus 400 of the present disclosure may have a plurality of regions in the first electrode 410, each with a different height. In one or more embodiments, in descending order of size, the display apparatus 400 may include the first region 410A1 with the first height h1, the second region 410A2 with the second height h2, and the third region 410A3 with the third height h3. In one or more embodiments, the display apparatus 400 may include the intermediate region 410AM having the intermediate height hm with a value between the first height h1 and the second height h2.

Through these height differences, in the regions corresponding to the first electrode 410, it may be feasible to improve or enhance light efficiency by introducing variations in optical resonance between the first electrode 410 and the second electrode 430 in each region.

As an example, among the regions of the first electrode 410, the region including the center of the region from which light is reflected and extracted forward, for example, the region including the center of the opening region OBMA of the light-blocking member OBM, may be formed with the highest first height h1, allowing the light to be reflected and extracted at a larger angle toward a side surface, and the region farther away from the center of the region from which the light is extracted forward, for example, the region farther away from the center of the opening region OBMA of the light-blocking member OBM, may be formed with the second height h2, which is lower than the first height h1, allowing the light to be reflected and extracted at a smaller angle toward the side surface.

In one or more embodiments, the intermediate region 410AM may be formed between the first region 410A1 and the second region 410A2, and, for example, the intermediate pattern layer 413 may be formed between the first pattern layer 411 and the second pattern layer 412 to be connected to or integrated with the first pattern layer 411 and the second pattern layer 412. Through this, the difference in optical resonance between adjacent regions of the first electrode 410 may be gradually adjusted, thereby improving or enhancing the uniformity of light efficiency, and a defect rate during the formation of the first electrode 410 may be reduced, thereby securing stable manufacturing characteristics of the first electrode 410.

Furthermore, among the regions of the first electrode 410 from which light is reflected and extracted forward, the region adjacent to the edge, for example, the region adjacent to the boundary line of the opening region OBMA of the light-blocking member OBM, may be formed with the lowest third height h3, as the first pattern layer 411, the second pattern layer 412, and the intermediate pattern layer 413 are not present.

Accordingly, the efficiency of light reflected by the first electrode 410 and extracted may be improved or enhanced. In one or more embodiments, by reducing or preventing the light reflected by the first electrode 410 and extracted from being blocked by the light-blocking member OBM, the light extraction efficiency may be improved or enhanced along with the effect of light efficiency through the optical resonance of the first electrode 410. As a result, the display apparatus 400 may be implemented with improved or enhanced image quality characteristics.

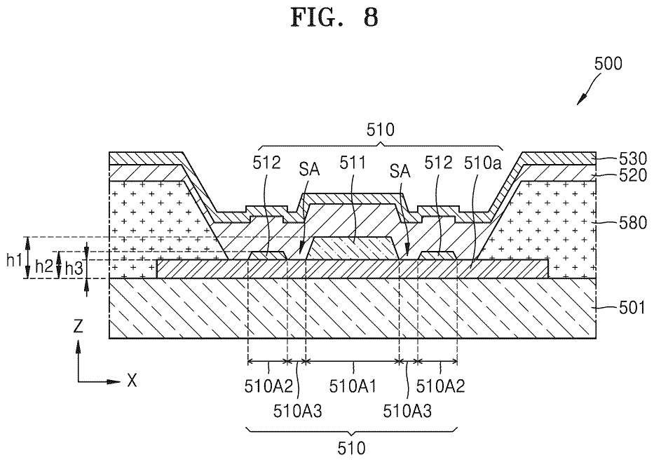

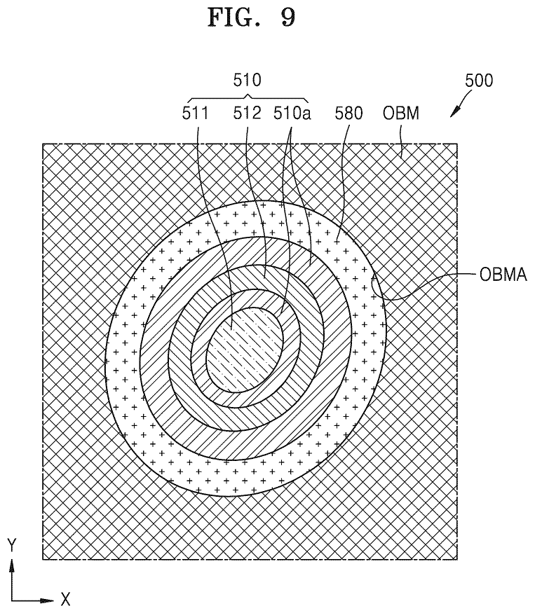

FIG. 8 is a cross-sectional view schematically illustrating a display apparatus according to one or more embodiments of the present disclosure. FIG. 9 is a schematic plan view of FIG. 8, viewed from one direction.

Referring to FIGS. 8 and 9, a display apparatus 500 may include a substrate 501, a first electrode 510, a second electrode 530, and an intermediate layer 520.

In one or more embodiments, the display apparatus 500 may further include one or more thin-film transistors, a pixel defining film 580, and/or the like arranged on the substrate 501.

For convenience of description, differences from the foregoing embodiments will be mainly or predominantly described herein in more detail.

The substrate 501 may include one or more suitable materials. In more detail, the substrate 501 may be formed or composed of glass, metal, an organic material, and/or other suitable materials, and the details thereof may be modified and applied within a range that is substantially the same or similar to the substrate 101 of one or more embodiments, and thus, more detailed descriptions thereof may not be provided.

In one or more embodiments, one or more buffer layers may be arranged on the substrate 501, for example, in a manner similar to the buffer layer 202 of FIG. 2, and a detailed description thereof may be substantially the same as provided in FIG. 2.

In one or more embodiments, one or more thin-film transistors may be arranged as illustrated in FIG. 2.

The first electrode 510 may be arranged on the substrate 501. The thin-film transistor may be arranged as described in one or more embodiments, and the first electrode 510 may be arranged above (e.g., on) an insulating (e.g., electrically insulating) layer arranged on the thin-film transistor. The first electrode 510 may contain one or more suitable conductive (e.g., electrically conductive) materials, and the materials of the first electrode 510 may be substantially the same as the materials of the first electrode 510 as described in one or more embodiments, and thus, a more detailed description thereof may not be provided.

In one or more embodiments, the first electrode 510 may include a first region 510A1 having a first height h1 with respect to an upper surface of the substrate 501 and second regions 510A2, each of the second regions 510A2 having a second height h2 with respect to the upper surface of the substrate 501.

In one or more embodiments, the second height h2 may have a smaller value than (e.g., may be lower than) the first height h1. In one or more embodiments, it may be seen that the first region 510A1 has a shape that is formed higher or protrudes more than the second region 510A2 with respect to the upper surface of the substrate 501.

In one or more embodiments, the first electrode 510 may include a third region 510A3 having a third height h3 with respect to the upper surface of the substrate 501, and the third height h3 of the third region 510A3 may have a smaller value than (e.g., may be lower than) the second height h2 of the second region 510A2.

In one or more embodiments, the third height h3 of the third region 510A3 may have a smaller value than (e.g., may be lower than) a height hm of an intermediate region 510AM.

The first region 510A1 of the first electrode 510 may be arranged between the second regions 510A2, which are arranged on at least opposite sides of the first region 510A1 of the first electrode 510 (e.g., between two of the second regions 510A2 that are opposite to each other). In one or more embodiments, the first region 510A1 may be surrounded by the second regions 510A2. For example, the first region 510A1 may be arranged in a region including a central portion of a region defined by an opening of the pixel defining film 580 or a central portion of a region defined by an opening of a light-blocking member. The second regions 510A2 may be spaced and/or apart (e.g., spaced apart or separated) from the first region 510A1 and may be around (e.g., surround) the first region 510A1.

The third region 510A3 of the first electrode 510 may be arranged adjacent to the second region 510A2. In one or more embodiments, the third region 510A3 may be adjacent to the second region 510A2 and may be arranged adjacent to a side surface of the second region 510A2 that is opposite to a side surface opposite to (e.g., facing) the first region 510A1.

In one or more embodiments, the third region 510A3 may be formed or arranged in a region in which the first region 510A1 or the second region 510A2 is not formed.

The structure in which the first electrode 510 is arranged on the substrate 501 will be described herein in more detail.

The first electrode 510 may include a base layer 510a, a first pattern layer 511, and a second pattern layer 512.

The base layer 510a may correspond to the entire (e.g., substantially entire) region of the first electrode 510, and, for example, may correspond to the first region 510A1, the second region 510A2, and the third region 510A3.

The first pattern layer 511 may be formed or arranged on the base layer 510a, for example, to be in contact with an upper surface of the base layer 510a, with a (e.g., set or predetermined) thickness.

The second pattern layer 512 may be formed or arranged on the base layer 510a, for example, to be in contact with the upper surface of the base layer 510a, with a thickness that is at least less than a thickness of the first pattern layer 511.

In one or more embodiments, the base layer 510a may have a thickness, which may correspond to the thickness of the third region 510A3. A total thickness of the base layer 510a and the first pattern layer 511 may correspond to the thickness of the first region 510A1. A total thickness of the base layer 510a and the second pattern layer 512 may correspond to the thickness of the second region 510A2.

By controlling these thicknesses, the first electrode 510 may have different heights in each region.

The first pattern layer 511 and the second pattern layer 512 may be arranged spaced and/or apart (e.g., spaced apart or separated) from each other, for example, with a separation space therebetween.

The base layer 510a may be formed or composed of a material different from a material of the first pattern layer 511 and the second pattern layer 512 so as to be distinguished therefrom, and the first pattern layer 511 and the second pattern layer 512 may be formed or composed of substantially the same material.

In one or more embodiments, the base layer 510a may be formed or composed of substantially the same material as the first pattern layer 511 and the second pattern layer 512.

In one or more embodiments, the first region 510A1 of the first electrode 510 may correspond to the base layer 510a and the first pattern layer 511, the second region 510A2 of the first electrode 510 may correspond to the base layer 510a and the second pattern layer 512, and the third region 510A3 of the first electrode 510 may correspond to the region in which the base layer 510a is present.

By allowing the first electrode 510 to include the base layer 510a, the first pattern layer 511, and the second pattern layer 512, the first region 510A1, the second region 510A2, and the third region 510A3, which are the regions of different heights, may be easily or suitably implemented. In one or more embodiments, through this structure of the first electrode 510, differential resonance structures may be implemented within the pixel, thereby improving or enhancing light efficiency.

The second electrode 530 may be opposite to (e.g., face) the first electrode 510. The second electrode 530 may be formed or composed of one or more suitable conductive (e.g., electrically conductive) materials. In one or more embodiments, the second electrode 530 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 520 may include an organic light-emitting layer and may be arranged between the first electrode 510 and the second electrode 530. A low-molecular-weight organic material and/or a high-molecular-weight organic material may be utilized for the organic light-emitting layer of the intermediate layer 520. In one or more embodiments, the intermediate layer 520 may further include at least one selected from the group consisting of a hole injection layer, a hole transport layer, an electron transport layer, and an electron injection layer, in addition to the organic light-emitting layer.

After the pixel defining film 580 is arranged so as not to cover a set or predetermined region of the first electrode 510, the intermediate layer 520 may be arranged on the region of the first electrode 510 that is not covered by the pixel defining film 580, and the second electrode 530 may be arranged on the intermediate layer 520.

The pixel defining film 580 may be formed or composed of one or more suitable insulating (e.g., electrically insulating) materials. In one or more embodiments, the pixel defining film 580 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 580 may include a material that reduces or blocks the reflection of light incident from the outside, and, for example, may include a black organic material, a dark-colored organic material, and/or a black pigment.

In one or more embodiments, an encapsulation portion may further be arranged, and details thereof may be substantially the same as illustrated in FIG. 2 of one or more embodiments.

In one or more embodiments, a light-blocking member OBM may be arranged as illustrated in FIG. 9, and referring to FIG. 9, an opening region OBMA of the light-blocking member OBM may include a curved edge, such as a slanted circular or elliptical edge.

The first pattern layer 511 of the first electrode 510 may be arranged in a region including a central region of the opening region OBMA, and the second pattern layer 512 may be spaced and/or apart (e.g., spaced apart or separated) from the first pattern layer 511 and may be around (e.g., surround) the first pattern layer 511. In one or more embodiments, the second pattern layer 512 may be spaced and/or apart (e.g., spaced apart or separated) from a boundary line of the opening region OBMA.

In one or more embodiments, the base layer 510a may be arranged in a gap between the first pattern layer 511 and the second pattern layer 512, and in a space between the second pattern layer 512 and the boundary line of the opening region OBMA.

In one or more embodiments, these regions of the first pattern layer 511, the second pattern layer 512, and the base layer 510a as illustrated in FIG. 9 may correspond to the first region 510A1, the second region 510A2, and the third region 510A3 of the first electrode 510, respectively.

In one or more embodiments, a color filter layer may be located or arranged above (e.g., on) the opening region OBMA of the light-blocking member OBM and a portion of the light-blocking member OBM, and this may be substantially the same as described in one or more embodiments of FIG. 2.

In one or more embodiments, a cover member may further be arranged, and the cover member may be substantially the same as described in one or more embodiments of FIG. 2.

In one or more embodiments, the display apparatus 500 may include one or more touch pattern layers, such as one or more conductive (e.g., electrically conductive) patterns, as described in one or more embodiments of FIG. 2.

In one or more embodiments, the shape of an upper surface of the first electrode 510 may be at least partially implemented in the intermediate layer 520 and the second electrode 530. In one or more embodiments, among the regions of the second electrode 530, the region corresponding to the first pattern layer 511 of the first electrode 510 may have a shape protruded upward, and the region corresponding to the second pattern layer 512 of the first electrode 510 may have a shape protruded upward less than the region corresponding to the first pattern layer 511.

The display apparatus 500 of the present disclosure may have a plurality of regions in the first electrode 510, each with a different height. In one or more embodiments, in descending order of size, the display apparatus 500 may include the first region 510A1 with the first height h1, the second region 510A2 with the second height h2, and the third region 510A3 with the third height h3.

Through these height differences, in the regions corresponding to the first electrode 510, it may be feasible to improve or enhance light efficiency by introducing variations in optical resonance between the first electrode 510 and the second electrode 530 in each region.

As an example, among the regions of the first electrode 510, the region including the center of the region from which light is reflected and extracted forward, for example, the region including the center of the opening region OBMA of the light-blocking member OBM, may be formed with the highest first height h1, allowing the light to be reflected and extracted at a larger angle toward a side surface, and the region farther away from the center of the region from which the light is extracted forward, for example, the region farther away from the center of the opening region OBMA of the light-blocking member OBM, may be formed with the second height h2, which is lower than the first height h1, allowing the light to be reflected and extracted at a smaller angle toward the side surface.

Furthermore, by forming the boundary line of the region that defines the region from which light is extracted, such as the opening region OBMA of the light-blocking member OBM, in a slanted or elliptical shape, pixels that control one or more suitable optical characteristics or the display apparatus 500 including the pixels may be implemented, and the characteristics of light efficiency for each pixel or region of the display apparatus 500 may be precisely or suitably controlled or selected.

Furthermore, among the regions of the first electrode 510 from which light is reflected and extracted forward, the region adjacent to the edge, for example, the region adjacent to the boundary line of the opening region OBMA of the light-blocking member OBM may be formed with the lowest third height h3, as there are no first pattern layer 511 or second pattern layer 512.

Accordingly, the efficiency of light reflected by the first electrode 510 and extracted may be improved or enhanced. In one or more embodiments, by reducing or preventing the light reflected by the first electrode 510 and extracted from being blocked by the light-blocking member OBM, the light extraction efficiency may be improved or enhanced along with the effect of light efficiency through the optical resonance of the first electrode 510. As a result, the display apparatus 500 may be implemented with improved or enhanced image quality characteristics.

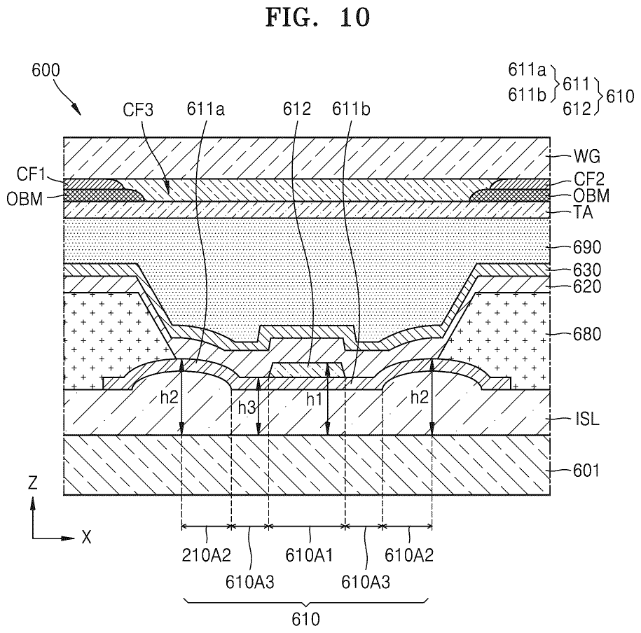

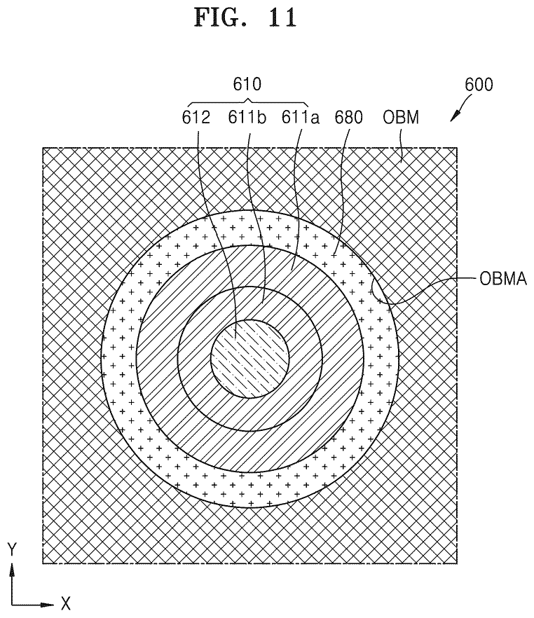

FIG. 10 is a cross-sectional view schematically illustrating a display apparatus according to one or more embodiments of the present disclosure. FIG. 11 is a schematic plan view of FIG. 10, viewed from one direction. In one or more embodiments, FIG. 11 is a plan view of FIG. 10 viewed from above a cover member WG.

Referring to FIGS. 10 and 11, a display apparatus 600 may include a substrate 601, a first electrode 610, a second electrode 630, and an intermediate layer 620.

In one or more embodiments, the display apparatus 600 may further include one or more thin-film transistors, a pixel defining film 680, and/or the like arranged on the substrate 601.

For convenience of description, differences from the foregoing embodiments will be mainly or predominantly described herein in more detail.

The substrate 601 may include one or more suitable materials. In more detail, the substrate 601 may be formed or composed of glass, metal, an organic material, and/or other suitable materials, and the details thereof may be modified and applied within a range that is substantially the same or similar to the substrate 601 as described in one or more embodiments, and thus, more detailed descriptions thereof may not be provided.

In one or more embodiments, one or more insulating layers ISL may be arranged on the substrate 601.

The insulating layers ISL may be arranged on the substrate 601. In one or more embodiments, one or more circuits, such as thin-film transistors, may be arranged on the substrate 601, and the insulating layer ISL may be formed or arranged adjacent to or on the thin-film transistors.

The insulating layer ISL may contain one or more suitable materials, e.g., inorganic materials, and may also contain organic materials.

In one or more embodiments, one or more thin-film transistors may be arranged between the substrate 601 and the insulating layer ISL, and examples thereof may be substantially the same as described in one or more embodiments with reference to FIG. 2. In this case, the insulating layer ISL of the present disclosure may correspond to the passivation film 208 as illustrated in FIG. 2, or, as another example, may be an upper film of the passivation film 208.

The first electrode 610 may be arranged on the insulating layer ISL. The first electrode 610 may contain one or more suitable conductive (e.g., electrically conductive) materials, and the materials of the first electrode 610 may be substantially the same as the materials of the first electrode 610 as described in one or more embodiments, and thus, a more detailed description thereof may not be provided.

The first electrode 610 may include a base layer 611 and a pattern layer 612.

The base layer 611 may be formed or arranged on the insulating layer ISL, for example, to be in contact with the insulating layer ISL. In one or more embodiments, if (e.g., when) the thin-film transistor is arranged below the first electrode 610, the base layer 611 may be electrically connected to the source electrode or the drain electrode of the thin-film transistor, and, for example, may be in contact therewith.

The base layer 611 may include one or more curved portions 611a and a flat portion 611b.

The curved portion 611a of the base layer 611 may include a convex surface, and, for example, may include a convex surface protruded in a direction toward the second electrode 630.

The curved portion 611a may have a surface corresponding to the insulating layer ISL therebelow. In one or more embodiments, the convex surface of the curved portion 611a may have a shape corresponding to a convex surface of the insulating layer ISL.

The flat portion 611b of the base layer 611 may be formed or arranged adjacent to the curved portion 611a. In one or more embodiments, the flat portion 611b of the base layer 611 may be arranged between the curved portions 611a that are on opposite sides, and, for example, may be surrounded by the curved portions 611a.

The base layer 611 may correspond to the entire (e.g., substantially entire) region of the first electrode 610, and, for example, may correspond to the first region 610A1, the second region 610A2, and the third region 610A3.

The pattern layer 612 may be formed or arranged on the base layer 611, for example, to be in contact with an upper surface of the base layer 611, with a (e.g., set or predetermined) thickness.

In one or more embodiments, the pattern layer 612 may be formed or arranged on the base layer 611, for example, on the flat portion 611b. For example, the pattern layer 612 may be arranged so as not to overlap the curved portion 611a of the base layer 611.

As an example, the pattern layer 612 may be arranged between the curved portions 611a that are on opposite sides of the base layer 611, and, for example, may be surrounded by the curved portions 611a.

In one or more embodiments, the pattern layer 612 may be spaced and/or apart (e.g., spaced apart or separated) from the curved portions 611a, and, for example, may be arranged with a separation space therebetween, and the separation space may be a region corresponding to the flat portion 611b.

In one or more embodiments, the pattern layer 612 may have an upper surface, such as the surface opposite to (e.g., facing) the second electrode 630, which may be at least partially flat.

The base layer 611 and the pattern layer 612 may be formed or composed of different materials so as to be distinguished from each other.

In one or more embodiments, the base layer 611 may be formed or composed of substantially the same material as the pattern layer 612.

In one or more embodiments, the first electrode 610 may include the first region 610A1 having a first height h1 with respect to an upper surface of the substrate 601 and the second region 610A2 having a second height h2 with respect to the upper surface of the substrate 601.

The first region 610A1 having the first height h1 may be a region relatively close to the center of a region from which light is extracted, which may allow light to be extracted at a high angle toward a side surface, thereby improving or enhancing light efficiency.

In one or more embodiments, the second region 610A2 having the second height h2 may be a surface corresponding to the curved portion 611a and may control one or more suitable emission directions of light in a region adjacent to an edge of the region from which light is extracted, thereby improving or enhancing the light efficiency.

The values of the first height h1 and the second height h2 may be suitably controlled or selected. In one or more embodiments, by setting or predetermining the first height h1 higher than the second height h2, light extraction efficiency in the central region, in which light is reflected more widely toward the side surface, may be improved by preventing or reducing the light from being blocked.

Further, as another example, by setting or predetermining the values of the first height h1 and the second height h2 to be equal or similar to each other, it may be feasible to enhance the control of light extraction from the convex surface of the curved portion, thereby improving or enhancing light concentration. As another example, by setting or predetermining the second height h2 higher than the first height h1, it may be feasible to precisely or suitably implement light uniformity control in a single pixel.

In one or more embodiments, the first electrode 610 may include the third region 610A3 having the third height h3 with respect to the upper surface of the substrate 601, and the third height h3 of the third region 610A3 may have a smaller value than (e.g., may be lower than) the first height h1 and the second height h2.

The first region 610A1 of the first electrode 610 may be arranged between the second regions 610A2, which are arranged on at least opposite sides of the first region 610A1 of the first electrode 610 (e.g., between two of the second regions 610A2 that are opposite to each other). In one or more embodiments, the first region 610A1 may be surrounded by the second regions 610A2. For example, the first region 610A1 may be arranged in a region including a central portion of a region defined by an opening of the pixel defining film 680 or a central portion of a region defined by an opening OBMA of a light-blocking member OBM to be described herein in more detail. The second regions 610A2 may be spaced and/or apart (e.g., spaced apart or separated) from the first region 610A1 and may be around (e.g., surround) the first region 610A1.

The third region 610A3 of the first electrode 610 may be arranged adjacent to the first region 610A1 or the second region 610A2. In one or more embodiments, the third region 610A3 may be arranged between the first region 610A1 and the second region 610A2.

In one or more embodiments, the third region 610A3 may be formed in a region in which the first region 610A1 or the second region 610A2 is not formed.

The base layer 611 may correspond to the entire (e.g., substantially entire) region of the first electrode 610, and, for example, may correspond to the first region 610A1, the second region 610A2, and the third region 610A3.

In one or more embodiments, the first region 610A1 of the first electrode 610 may correspond to the base layer 611 and the pattern layer 612, the second region 610A2 of the first electrode 610 may correspond to the curved portion 611a of the base layer 611, and the third region 610A3 of the first electrode 610 may correspond to a region in which only the flat portion 611b of the base layer 611 is present.

By allowing the first electrode 610 to include the base layer 611 and the pattern layer 612, the first region 610A1, the second region 610A2, and the third region 610A3, which are the regions with different heights or upper surface shapes, may be easily or suitably implemented. In one or more embodiments, through this structure of the first electrode 610, differential resonance structures may be implemented within the pixel, thereby improving or enhancing light efficiency.

The second electrode 630 may be opposite to (e.g., face) the first electrode 610. The second electrode 630 may be formed or composed of one or more suitable conductive (e.g., electrically conductive) materials. In one or more embodiments, the second electrode 630 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 620 may include an organic light-emitting layer and may be arranged between the first electrode 610 and the second electrode 630. A low-molecular-weight organic material and/or a high-molecular-weight organic material may be utilized for the organic light-emitting layer of the intermediate layer 620. In one or more embodiments, the intermediate layer 620 may further include at least one selected from the group consisting of a hole injection layer, a hole transport layer, an electron transport layer, and an electron injection layer, in addition to the organic light-emitting layer.

After the pixel defining film 680 is arranged so as not to cover a set or predetermined region of the first electrode 610, the intermediate layer 620 may be arranged on the region of the first electrode 610 that is not covered by the pixel defining film 680, and the second electrode 630 may be arranged on the intermediate layer 620.

The pixel defining film 680 may be formed or composed of one or more suitable insulating (e.g., electrically insulating) materials. In one or more embodiments, the pixel defining film 680 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 680 may include a material that reduces or blocks the reflection of light incident from the outside, and, for example, may include a black organic material, a dark-colored organic material, and/or a black pigment.

An encapsulation portion 690 may be arranged above (e.g., on) the second electrode 630. As an example, the encapsulation portion 690 may include one or a plurality of encapsulation layers. In one or more embodiments, the encapsulation portion 690 may include one or more inorganic layers or one or more organic layers. As an example, the encapsulation portion 690 may have a structure in which inorganic layers and organic layers are alternately stacked at least once, and, for example, may have a structure in which inorganic layers and organic layers are alternately stacked two or more times.

In one or more embodiments, a light-blocking member OBM may further be arranged above (e.g., on) the encapsulation portion 690. The light-blocking member OBM may include an opening region OBMA that allows light generated from below, such as light generated by the intermediate layer 620 or light reflected by the first electrode 610 and extracted, to pass therethrough. The light-blocking member OBM may be a black matrix (BM) that blocks light (or reduces a degree or occurrence of light).

In one or more embodiments, referring to FIG. 11, the opening region OBMA of the light-blocking member OBM may include a curved edge, such as a circular (e.g., substantially circular) edge.

FIG. 11 is a schematic plan view of FIG. 10 viewed form one direction and illustrates only the light-blocking member OBM, the pixel defining film 680, and the first electrode 610 for convenience of description.

The pattern layer 612 of the first electrode 610 may be arranged in a region including a central region of the opening region OBMA, and the curved portion 611a may be spaced and/or apart (e.g., spaced apart or separated) from and may be around (e.g., surround) the pattern layer 612. In one or more embodiments, the curved portion 611a may be spaced and/or apart (e.g., spaced apart or separated) from a boundary line of the opening region OBMA.

In one or more embodiments, the flat portion 611b of the base layer 611 may be located or arranged in a gap between the pattern layer 612 and the curved portion 611a.

In one or more embodiments, color filter layers CF1, CF2, and CF3 may be located or arranged above (e.g., on) the opening region OBMA of the light-blocking member OBM and a portion of the light-blocking member OBM. Each of the color filter layers CF1, CF2, and CF3 may have a different color.

In one or more embodiments, the cover member WG may be located or arranged above (e.g., on) the light-blocking member OBM and the color filter layers CF1, CF2, and CF3, and the cover member WG may include a glass material.

In one or more embodiments, the display apparatus 600 may include one or more touch pattern layers TA, such as one or more conductive (e.g., electrically conductive) patterns. The touch pattern layers TA may be formed or arranged on an upper surface of the encapsulation portion 690, or, in one or more embodiments, on a lower or upper surface of the cover member WG.

In one or more embodiments, the shape of an upper surface of the first electrode 610 may be at least partially implemented in the intermediate layer 620 and the second electrode 630. In one or more embodiments, the regions of the second electrode 630 corresponding to the curved portion 611a, the flat portion 611b, and the pattern layer 612 of the first electrode 610 may have an upward protruded shape.

In the display apparatus 600 of the present disclosure, the first electrode 610 may include a base layer and a pattern portion, and the base layer may include a curved portion. These curved portions may be around (e.g., surround) the pattern portion. The pattern portion may be arranged in a region that includes the center of a region from which light is reflected and extracted, and the curved portions may be around (e.g., surround) the pattern portion. Accordingly, precise or suitable light control at the center and periphery of the light extraction region may be facilitated, thereby improving or enhancing light efficiency.

In one or more embodiments, by precisely or suitably controlling the heights of the first region, the second region, and the third region of the first electrode, optical resonance between the first electrode 610 and the second electrode 630 may vary across different regions corresponding to the first electrode 610, thereby improving or enhancing light efficiency.

FIG. 10 is a cross-sectional view schematically illustrating a display apparatus according to one or more embodiments of the present disclosure. FIG. 11 is a schematic plan view of FIG. 10, viewed from one direction.

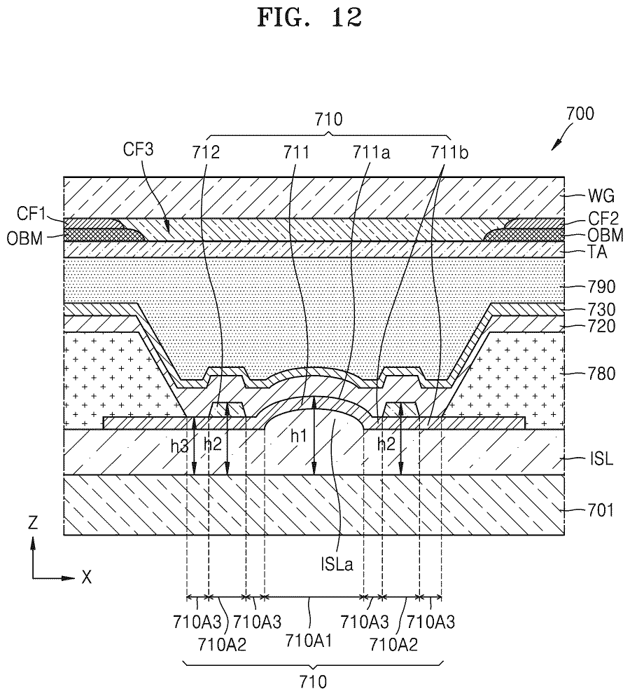

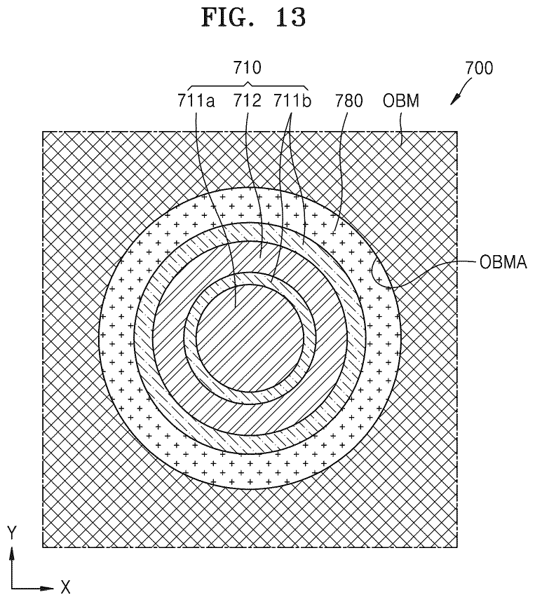

FIG. 12 is a cross-sectional view schematically illustrating a display apparatus according to one or more embodiments of the present disclosure. FIG. 13 is a schematic plan view of FIG. 12, viewed from one direction. In one or more embodiments, FIG. 13 is a plan view of FIG. 12 viewed from above a cover member WG.

Referring to FIGS. 12 and 13, a display apparatus 700 may include a substrate 701, a first electrode 710, a second electrode 730, and an intermediate layer 720.

In one or more embodiments, the display apparatus 700 may further include one or more thin-film transistors, a pixel defining film 780, and/or the like arranged on the substrate 701.

For convenience of description, differences from the foregoing embodiments will be mainly or predominantly described herein in more detail.

The substrate 701 may include one or more suitable materials. In more detail, the substrate 701 may be formed or composed of glass, metal, an organic material, and/or other suitable materials, and the details thereof may be modified and applied within a range that is substantially the same or similar to the substrate 101 as described in one or more embodiments, and thus, more detailed descriptions thereof may not be provided.

In one or more embodiments, one or more insulating layers ISL may be arranged on the substrate 701.

The insulating layers ISL may be arranged on the substrate 701. In one or more embodiments, one or more circuits, such as thin-film transistors, may be arranged on the substrate 701, and the insulating layer ISL may be formed or arranged adjacent to or on the thin-film transistors.

The insulating layer ISL may contain one or more suitable materials, e.g., inorganic materials, and may also contain organic materials.

In one or more embodiments, one or more thin-film transistors may be arranged between the substrate 701 and the insulating layer ISL, and examples thereof may be substantially the same as described in one or more embodiments with reference to FIG. 2. In this case, the insulating layer ISL of the present disclosure may correspond to the passivation film 208 as illustrated in FIG. 2, or, as another example, may be an upper film of the passivation film 208.

The first electrode 710 may be arranged on the insulating layer ISL. The first electrode 710 may contain one or more suitable conductive (e.g., electrically conductive) materials, and the materials of the first electrode 710 may be substantially the same as the materials of the first electrode 710 as described in one or more embodiments, and thus, a more detailed description thereof may not be provided.

The first electrode 710 may include a base layer 711 and a pattern layer 712.

The base layer 711 may be formed or arranged on the insulating layer ISL, for example, to be in contact with the insulating layer ISL. In one or more embodiments, if (e.g., when) the thin-film transistor is arranged below the first electrode 710, the base layer 711 may be electrically connected to the source electrode or the drain electrode of the thin-film transistor, and, for example, may be in contact therewith.

The base layer 711 may include a curved portion 711a and flat portions 711b.

The curved portion 711a of the base layer 711 may include a convex surface, and, for example, may include a convex surface protruded in a direction toward the second electrode 730.

The curved portion 711a may have a surface corresponding to the insulating layer ISL therebelow. In one or more embodiments, the convex surface of the curved portion 711a may have a shape corresponding to a convex surface ISLa of the insulating layer ISL.

The flat portions 711b of the base layer 711 may be formed or arranged adjacent to the curved portion 711a. In one or more embodiments, the flat portions 711b of the base layer 711 may be arranged on opposite sides of the curved portion 711a, with the curved portion 711a in between, and, for example, the flat portions 711b may be around (e.g., surround) the curved portion 711a.

The base layer 711 may correspond to the entire (e.g., substantially entire) region of the first electrode 710, and, for example, may correspond to the first region 710A1, the second regions 710A2, and the third regions 710A3.

The pattern layer 712 may be formed or arranged on the base layer 711, for example, to be in contact with an upper surface of the base layer 711, with a (e.g., set or predetermined) thickness.

In one or more embodiments, the pattern layer 712 may be formed or arranged on the base layer 711, for example, on the flat portion 711b. For example, the pattern layer 712 may not overlap the curved portion 711a of the base layer 711.

As an example, the pattern layer 712 may be arranged on opposite sides of the curved portion 711a of the base layer 711, and, for example, may be around (e.g., surround) the curved portion 711a.

In one or more embodiments, the pattern layer 712 may be spaced and/or apart (e.g., spaced apart or separated) from the curved portion 711a, and, for example, may be arranged with a separation space therebetween, and the separation space may be a region corresponding to the flat portion 711b.

In one or more embodiments, the pattern layer 712 may have an upper surface, such as the surface opposite to (e.g., facing) the second electrode 730, which may be at least partially flat.

The base layer 711 and the pattern layer 712 may be formed or composed of different materials so as to be distinguished from each other.

In one or more embodiments, the base layer 711 may be formed or composed of substantially the same material as the pattern layer 712.

In one or more embodiments, the first electrode 710 may include the first region 710A1 having a first height h1 with respect to an upper surface of the substrate 701 and the second regions 710A2, each of the second regions 710A2 having a second height h2 with respect to the upper surface of the substrate 701.

The first region 710A1 having the first height h1 may be a region relatively close to the center of a region from which light is extracted, which may allow light to be extracted at a high angle toward a side surface, thereby improving or enhancing light efficiency. In one or more embodiments, the first region 710A1 may be a region corresponding to the curved portion 711a and may control one or more suitable emission directions of light from the region, thereby improving or enhancing light efficiency. If (e.g., when) light concentration is needed or desired in the central region, the curvature may be controlled or selected to reduce a light emission angle toward the side surfaces, thereby improving or enhancing light concentration.

In one or more embodiments, the second region 710A2 having the second height h2 may be a surface corresponding to the pattern layer 712 and may improve or enhance a light extraction angle on the side surface of a region, from which light is extracted, between the center and the edge of region, thereby enhancing light distribution, improving or enhancing the uniformity of light extraction, and improving or enhancing the overall light efficiency and light quality.

The values of the first height h1 and the second height h2 may be suitably controlled or selected. In one or more embodiments, by setting or predetermining the first height h1 higher than the second height h2, light extraction efficiency in the central region, in which light is reflected more widely toward the side surface, may be improved or enhanced by preventing or reducing the light from being blocked.

In one or more embodiments, as another example, by setting or predetermining the values of the first height h1 and the second height h2 to be equal or similar to each other, it may be feasible to enhance the control of light extraction from the convex surface of the curved portion, thereby improving or enhancing light concentration. As another example, by setting or predetermining the second height h2 higher than the first height h1, it may be feasible to precisely or suitably implement light uniformity control in a single pixel.

In one or more embodiments, the first electrode 710 may include the third region 710A3 having the third height h3 with respect to the upper surface of the substrate 701, and the third height h3 of the third region 710A3 may have a smaller value than (e.g., may be lower than) the first height h1 and the second height h2.

The first region 710A1 of the first electrode 710 may be arranged between the second regions 710A2, which are arranged on at least opposite sides of the first region 710A1 of the first electrode 710 (e.g., between two of the second regions 710A2 that are opposite to each other). In one or more embodiments, the first region 710A1 may be surrounded by the second regions 710A2. For example, the first region 710A1 may be arranged in a region including a central portion of a region defined by an opening of the pixel defining film 780 or a central portion of a region defined by an opening OBMA of a light-blocking member OBM to be described herein in more detail. The second regions 710A2 may be spaced and/or apart (e.g., spaced apart or separated) from the first region 710A1 and may be around (e.g., surround) the first region 710A1.

The third region 710A3 of the first electrode 710 may be arranged adjacent to the first region 710A1 or the second region 710A2. In one or more embodiments, the third region 710A3 may be arranged between the first region 710A1 and the second region 710A2.

In one or more embodiments, as another example, the third region 710A3 may be adjacent to the second region 710A2 and may be arranged adjacent to a side surface of the second region 710A2 that is opposite to a side surface opposite to (e.g., facing) the first region 710A1.

In one or more embodiments, the third region 710A3 may be formed or arranged in a region in which the first region 710A1 or the second region 710A2 is not formed.

The base layer 711 may correspond to the entire (e.g., substantially entire) region of the first electrode 710, and, for example, may correspond to the first region 710A1, the second regions 710A2, and the third regions 710A3.

In one or more embodiments, the first region 710A1 of the first electrode 710 may correspond to the curved portion 711a of the base layer 711, the second region 710A2 of the first electrode 710 may correspond to the pattern layer 712, and the third region 710A3 of the first electrode 710 may correspond to a region in which only the flat portion 711b of the base layer 711 is present.

By allowing the first electrode 710 to include the base layer 711 and the pattern layer 712, the first region 710A1, the second region 710A2, and the third region 710A3, which are the regions with different heights or upper surface shapes, may be easily or suitably implemented. In one or more embodiments, through this structure of the first electrode 710, differential resonance structures may be implemented within the pixel, thereby improving or enhancing light efficiency.

The second electrode 730 may be opposite to (e.g., face) the first electrode 710. The second electrode 730 may be formed or composed of one or more suitable conductive (e.g., electrically conductive) materials. In one or more embodiments, the second electrode 730 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 720 may include an organic light-emitting layer and may be arranged between the first electrode 710 and the second electrode 730. A low-molecular-weight organic material and/or a high-molecular-weight organic material may be utilized for the organic light-emitting layer of the intermediate layer 720. In one or more embodiments, the intermediate layer 720 may further include at least one selected from the group consisting of a hole injection layer, a hole transport layer, an electron transport layer, and an electron injection layer, in addition to the organic light-emitting layer.

After the pixel defining film 780 is arranged so as not to cover a set or predetermined region of the first electrode 710, the intermediate layer 720 may be arranged on the region of the first electrode 710 that is not covered by the pixel defining film 780, and the second electrode 730 may be arranged on the intermediate layer 720.

The pixel defining film 780 may be formed or composed of one or more suitable insulating (e.g., electrically insulating) materials. In one or more embodiments, the pixel defining film 780 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 780 may include a material that reduces or blocks the reflection of light incident from the outside, and, for example, may include a black organic material, a dark-colored organic material, and/or a black pigment.

An encapsulation portion 790 may be arranged above (e.g., on) the second electrode 730. As an example, the encapsulation portion 790 may include one or a plurality of encapsulation layers. In one or more embodiments, the encapsulation portion 790 may include one or more inorganic layers or one or more organic layers. As an example, the encapsulation portion 790 may have a structure in which inorganic layers and organic layers are alternately stacked at least once, and, for example, may have a structure in which inorganic layers and organic layers are alternately stacked two or more times.

In one or more embodiments, a light-blocking member OBM may further be above (e.g., on) the encapsulation portion 790. The light-blocking member OBM may include an opening region OBMA that allows light generated from below, such as light generated by the intermediate layer 720 or light reflected by the first electrode 710 and extracted, to pass therethrough. The light-blocking member OBM may be a black matrix (BM) that blocks light (or reduces a degree or occurrence of light).

In one or more embodiments, referring to FIG. 13, the opening region OBMA of the light-blocking member OBM may include a curved edge, such as a circular (e.g., substantially circular) edge.

FIG. 13 is a schematic plan view of FIG. 12 viewed form one direction and illustrates only the light-blocking member OBM, the pixel defining film 780, and the first electrode 710 for convenience of description.

The curved portion 711a of the first electrode 710 may be arranged in a region including a central region of the opening region OBMA, and the pattern layer 712 may be spaced and/or apart (e.g., spaced apart or separated) from and may be around (e.g., surround) the curved portion 711a. In one or more embodiments, the pattern layer 712 may be spaced and/or apart (e.g., spaced apart or separated) from a boundary line of the opening region OBMA.

In one or more embodiments, the flat portion 711b of the base layer 711 may be located or arranged in a gap between the curved portion 711a and the pattern layer 712.

In one or more embodiments, color filter layers CF1, CF2, and CF3 may be located or arranged above (e.g., on) the opening region OBMA of the light-blocking member OBM and a portion of the light-blocking member OBM. Each of the color filter layers CF1, CF2, and CF3 may have a different color.

In one or more embodiments, the cover member WG may be located or arranged above (e.g., on) the light-blocking member OBM and the color filter layers CF1, CF2, and CF3, and the cover member WG may include a glass material.

In one or more embodiments, the display apparatus 700 may include one or more touch pattern layers TA, such as one or more conductive (e.g., electrically conductive) patterns. The touch pattern layers TA may be formed or arranged on an upper surface of the encapsulation portion 790, or, in one or more embodiments, on a lower or upper surface of the cover member WG.

In one or more embodiments, the shape of an upper surface of the first electrode 710 may be at least partially implemented in the intermediate layer 720 and the second electrode 730. In one or more embodiments, the regions of the second electrode 730 corresponding to the curved portion 711a, the flat portion 711b, and the pattern layer 712 of the first electrode 710 may have an upward protruded shape.

In the display apparatus 700 of the present disclosure, the first electrode 710 may include a base layer and a pattern portion, and the base layer may include a curved portion. These curved portions may be around (e.g., surround) the pattern portion. The pattern portion may be arranged in a region that includes the center of a region from which light is reflected and extracted, and the curved portions may be around (e.g., surround) the pattern portion. Accordingly, precise or suitable light control at the center and periphery of the light extraction region may be facilitated, thereby improving or enhancing light efficiency.

In one or more embodiments, by precisely or suitably controlling the heights of the first region, the second region, and the third region of the first electrode, optical resonance between the first electrode 710 and the second electrode 730 may vary across different regions corresponding to the first electrode 710, thereby improving or enhancing light efficiency.

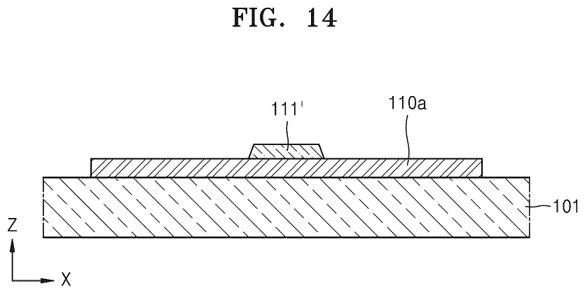

FIGS. 14 to 19 are views to schematically describe a method of manufacturing a display apparatus according to one or more embodiments of the present disclosure. For convenience of description, the manufacturing method of the present disclosure illustrates an example of a process of manufacturing the display apparatus of FIG. 1.

Referring to FIG. 14, a base layer 110a may be formed or arranged on a substrate 101. In one or more embodiments, one or more insulating (e.g., electrically insulating) layers may further be between the substrate 101 and the base layer 110a. As another example, a thin-film transistor may further be between the substrate 101 and the base layer 110a. These contents may be substantially the same as described in one or more embodiments.

A preliminary first pattern layer 111′ may be formed or arranged on the base layer 110a. The base layer 110a and the preliminary first pattern layer 111′ may be formed or composed of different materials so as to be distinguished from each other. In one or more embodiments, both (e.g., simultaneously) the base layer 110a and the preliminary first pattern layer 111′ may contain one or more suitable conductive (e.g., electrically conductive) materials, for example, utilizing one of the materials selected from the group consisting of transparent (e.g., substantially transparent) conductive (e.g., electrically conductive) oxides, such as indium tin oxide (ITO), indium zinc oxide (IZO), zinc oxide (e.g., ZnOₓ, wherein 0<x≤2; e.g., ZnO), indium oxide (e.g., In₂O₃), indium gallium oxide (IGO), and aluminum zinc oxide (AZO). As an example, the base layer 110a may contain indium tin oxide (ITO), while the preliminary first pattern layer 111′ may contain indium zinc oxide (IZO).

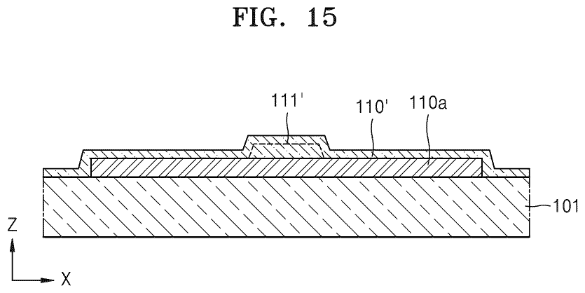

Thereafter, referring to FIG. 15, a preliminary layer 110′ may be formed or arranged. In one or more embodiments, the preliminary layer 110′ may contain substantially the same material as the preliminary first pattern layer 111′ and may cover the preliminary first pattern layer 111′ and be in contact with or cover the base layer 110a.

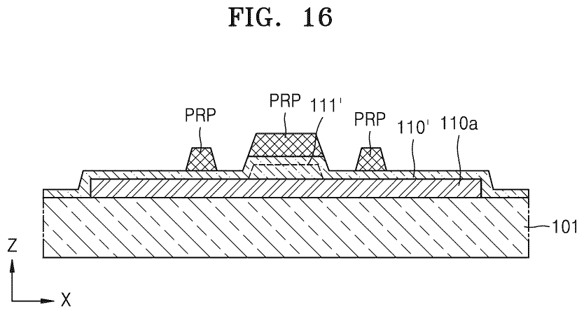

Thereafter, referring to FIG. 16, a patterning member PRP may be formed or arranged. The patterning member PRP may be an etch-resistant mask that blocks etching, and may include, for example, a photoresist that may be patterned by photolithography and/or the like.

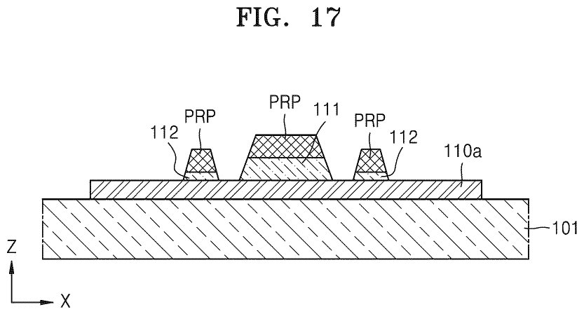

Referring to FIG. 17, an etching process may be performed utilizing the patterning member PRP, and accordingly, a first pattern layer 111 and a second pattern layer 112 may be formed or arranged on the base layer 110a.

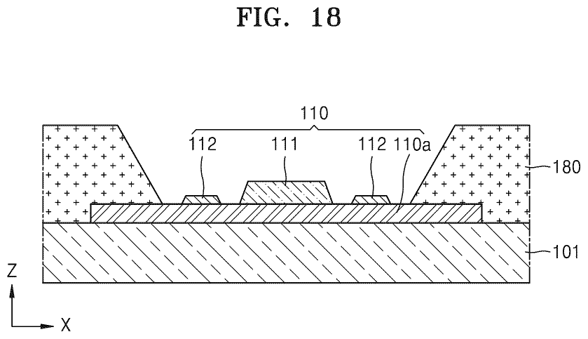

Referring to FIG. 18, the patterning member PRP on the first pattern layer 111 and the second pattern layer 112 may be removed, and a pixel defining film 180 may be formed or arranged.

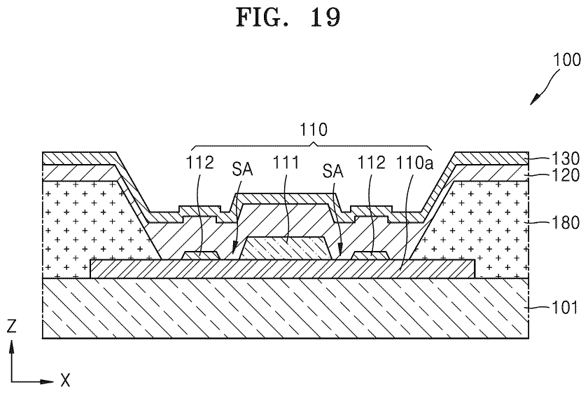

Referring to FIG. 19, an intermediate layer 120 and a second electrode 130 may be formed or arranged.

The contents, including the materials of the pixel defining film 180, the intermediate layer 120, and the second electrode 130, may be substantially the same as described with reference to FIGS. 1 and 2, and thus, more detailed descriptions thereof may not be provided.

By using the manufacturing method of the present disclosure, the precise or suitable shapes of the base layer 110a, the first pattern layer 111, and the second pattern layer 112 of the first electrode 110 may be easily or suitably implemented.

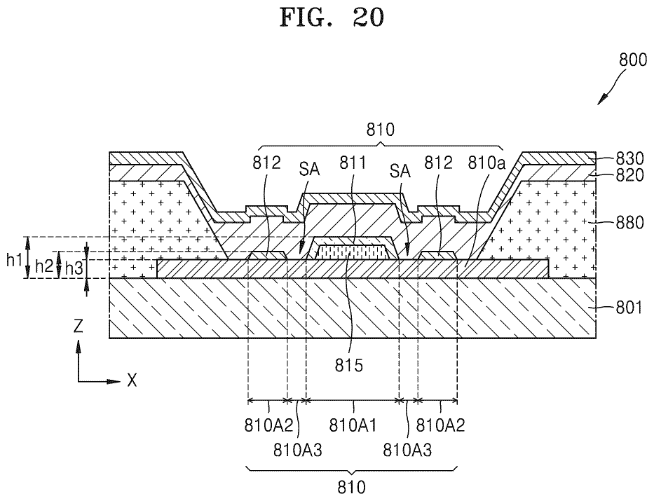

FIG. 20 is a cross-sectional view schematically illustrating a display apparatus according to one or more embodiments of the present disclosure.

Referring to FIG. 20, a display apparatus 800 may include a substrate 801, a first electrode 810, a second electrode 830, and an intermediate layer 820. In one or more embodiments, the display apparatus 800 may further include a heterogeneous layer 815. The heterogeneous layer 815 may overlap at least a portion of the first electrode 810. More details thereof are described herein.

In one or more embodiments, the display apparatus 800 may further include a pixel defining film 880.

For convenience of description, differences from the foregoing embodiments will be mainly or predominantly described herein in more detail.

The substrate 801 may include one or more suitable materials. In more detail, the substrate 801 may be formed or composed of glass, metal, and/or organic materials. The details of the substrate 801 may be modified and applied within a range that is substantially the same or similar to the substrate 101 as described in one or more embodiments, and thus, detailed descriptions thereof may not be provided.

In one or more embodiments, one or more buffer layers may be arranged on the substrate 801, for example, in a manner similar to the buffer layer 202 of FIG. 2, and a detailed description thereof may be substantially the same as provided in FIG. 2.

In one or more embodiments, one or more thin-film transistors may be arranged on the substrate 801 as illustrated in FIG. 2.

The first electrode 810 may be arranged on the substrate 801. In one or more embodiments, a thin-film transistor may be arranged on the substrate 801, and the first electrode 810 may be arranged on an insulating (e.g., electrically insulating) layer arranged on the thin-film transistor. In that case, one or more thin-film transistors may be arranged between the first electrode 810 and the substrate 801.

The first electrode 810 may have one or more suitable shapes, for example, the first electrode 810 may be patterned and formed in the shape of an island.

The first electrode 810 may contain one or more suitable conductive (e.g., electrically conductive) materials. As an example, the first electrode 810 may include at least one selected from the group consisting of transparent (e.g., substantially transparent) conductive (e.g., electrically conductive) oxides, such as indium tin oxide (ITO), indium zinc oxide (IZO), zinc oxide (e.g., ZnOₓ, wherein 0<x≤2; e.g., ZnO), indium oxide (e.g., In₂O₃), indium gallium oxide (IGO), and aluminum zinc oxide (AZO). In one or more embodiments, the first electrode 810 may include a highly reflective metal, such as silver (Ag).

In one or more embodiments, the first electrode 810 may include a first region 810A1 having a first height h1 with respect to an upper surface of the substrate 801 and second regions 810A2, each of the second regions 810A2 having a second height h2 with respect to the upper surface of the substrate 801.

In one or more embodiments, the second height h2 may have a smaller value than (e.g., may be lower than) the first height h1. In one or more embodiments, it may be seen that the first region 810A1 has a shape that is formed higher or protrudes more than the second region 810A2 with respect to the upper surface of the substrate 801.

In one or more embodiments, the first electrode 810 may include a third region 810A3 having a third height h3 with respect to the upper surface of the substrate 801, and the third height h3 of the third region 810A3 may have a smaller value than (e.g., may be lower than) the second height h2 of the second region 810A2.

The first region 810A1 of the first electrode 810 may be arranged between the second regions 810A2, which are arranged on at least opposite sides of the first region 810A1 of the first electrode 810 (e.g., between two of the second regions 810A2 that are opposite to each other). In one or more embodiments, the first region 810A1 may be surrounded by the second regions 810A2. For example, the first region 810A1 may be arranged in a region including a central portion of a pixel region defined by an opening of the pixel defining film 880. The second regions 810A2 may be spaced and/or apart (e.g., spaced apart or separated) from the first region 810A1 and may be around (e.g., surround) the first region 810A1.

The third region 810A3 of the first electrode 810 may be arranged adjacent to the first region 810A1 or the second region 810A2. In one or more embodiments, the third region 810A3 may be arranged between the first region 810A1 and the second region 810A2.

As another example, the third region 810A3 may be adjacent to the second region 810A2 and may be arranged adjacent to a side surface of the second region 810A2 that is opposite to a side surface opposite to (e.g., facing) the first region 810A1.

In one or more embodiments, the third region 810A3 may be formed or arranged in a region in which the first region 810A1 or the second region 810A2 is not formed.

The structure in which the first electrode 810 is arranged on the substrate 801 will be described herein in more detail.

The first electrode 810 may include a base layer 810a, a first pattern layer 811, and a second pattern layer 812.

The base layer 810a may correspond to the entire (e.g., substantially entire) region of the first electrode 810, and, for example, may correspond to the first region 810A1, the second regions 810A2, and the third regions 810A3.

The first pattern layer 811 may be formed or arranged on the base layer 810a, for example, to be in contact with an upper surface of the base layer 810a, with a (e.g., set or predetermined) thickness.

In one or more embodiments, the heterogeneous layer 815 may be arranged in at least one region between the base layer 810a and the first pattern layer 811. In one or more embodiments, the heterogeneous layer 815 may be arranged on the base layer 810a, and the first pattern layer 811 may be formed or arranged on the heterogeneous layer 815.

At this time, the first pattern layer 811 may be connected to at least the base layer 810a. In one or more embodiments, the first pattern layer 811 may correspond to at least one region of a side surface of the heterogeneous layer 815 and cover at least one region thereof, and, for example, the first pattern layer 811 may cover the heterogeneous layer 815. This may enable smooth electrical connection between the base layer 810a and the first pattern layer 811.

The heterogeneous layer 815 may be formed or composed of a material that is different at least from a material of the first pattern layer 811 and, for example, may be formed or composed of an insulating (e.g., electrically insulating) material. For example, the heterogeneous layer 815 may contain an inorganic material. In one or more embodiments, the heterogeneous layer 815 may be formed or composed of a material that is at least light-transmissive and, for example, may contain a transparent (e.g., substantially transparent) nitride and/or a transparent (e.g., substantially transparent) oxide. In one or more embodiments, the heterogeneous layer 815 may contain silicon nitride (e.g., SiNₓ, wherein 0<x≤2; e.g., Si₃N₄).

By utilizing the heterogeneous layer 815, an optical resonance effect may be maintained through light transmission, and by forming the heterogeneous layer 815 of a material different from a material of the first pattern layer 811, damage to the base layer 810a due to excessive or substantial etching during the formation of the first pattern layer 811 may be reduced or prevented. In one or more embodiments, during the formation of the first pattern layer 811, damage to the base layer 810a caused by a wet etching process, for example, the dissolution of conductive (e.g., electrically conductive) materials, such as silver (Ag), which may lead to the degradation of an oxide layer (e.g., an ITO layer), may be reduced or prevented.

In one or more embodiments, because the heterogeneous layer 815 may be formed using a dry etching process instead of a wet etching process, the number or duration of wet etching processes may be reduced, thereby enhancing the effect of reducing damage to the base layer 810a.

The second pattern layer 812 may be formed or arranged on the base layer 810a and, for example, may be in contact with the upper surface of the base layer 810a, and may have a thickness less than the total thickness of at least the heterogeneous layer 815 and the first pattern layer 811.

The first pattern layer 811 and the second pattern layer 812 may be arranged spaced and/or apart (e.g., spaced apart or separated) from each other, for example, with a separation space SA therebetween.

The base layer 810a may be formed or composed of a material different from a material of the first pattern layer 811 and the second pattern layer 812 so as to be distinguished therefrom, and the first pattern layer 811 and the second pattern layer 812 may be formed or composed of substantially the same material.

In one or more embodiments, the base layer 810a may be formed or composed of substantially the same material as the first pattern layer 811 and the second pattern layer 812.

In one or more embodiments, the first region 810A1 of the first electrode 810 may correspond to the base layer 810a, the heterogeneous layer 815, and the first pattern layer 811, the second region 810A2 of the first electrode 810 may correspond to the base layer 810a and the second pattern layer 812, and the third region 810A3 of the first electrode 810 may correspond to the region in which the base layer 810a is present.

The first electrode 810 may include the base layer 810a, the first pattern layer 811, and the second pattern layer 812, with the heterogeneous layer 815 arranged between the first pattern layer 811 and the base layer 810a, thereby facilitating the implementation of height-differentiated regions, which are the first region 810A1, the second region 810A2, and the third region 810A3. In one or more embodiments, through this structure of the first electrode 810, differential resonance structures may be implemented within the pixel, thereby improving or enhancing light efficiency.

The second electrode 830 may be opposite to (e.g., face) the first electrode 810. The second electrode 830 may be formed or composed of one or more suitable conductive (e.g., electrically conductive) materials. In one or more embodiments, the second electrode 830 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 820 may include an organic light-emitting layer and may be arranged between the first electrode 810 and the second electrode 830. A low-molecular-weight organic material and/or a high-molecular-weight organic material may be utilized for the organic light-emitting layer of the intermediate layer 820. In one or more embodiments, the intermediate layer 820 may further include at least one selected from the group consisting of a hole injection layer, a hole transport layer, an electron transport layer, and an electron injection layer, in addition to the organic light-emitting layer.

After the pixel defining film 880 is arranged so as not to cover a set or predetermined region of the first electrode 810, the intermediate layer 820 may be arranged on the region of the first electrode 810 that is not covered by the pixel defining film 880, and the second electrode 830 may be arranged on the intermediate layer 820.

The pixel defining film 880 may be formed or composed of one or more suitable insulating (e.g., electrically insulating) materials. In one or more embodiments, the pixel defining film 880 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 880 may include a material that reduces or blocks the reflection of light incident from the outside, and, for example, may include a black organic material, a dark-colored organic material, and/or a black pigment.

In one or more embodiments, an encapsulation portion may further be arranged, and details thereof may be substantially the same as illustrated in FIG. 2 of one or more embodiments.

In one or more embodiments, the display apparatus 800 may include the features as described in one or more embodiments and, for example, may further include a light-blocking member, a color filter layer, or a cover member, as illustrated in FIG. 2 or FIG. 5.

In one or more embodiments, the display apparatus 800 may include one or more touch pattern layers, such as one or more conductive (e.g., electrically conductive) patterns.

In one or more embodiments, the shape of an upper surface of the first electrode 810 may be at least partially implemented in the intermediate layer 820 and the second electrode 830. In one or more embodiments, among the regions of the second electrode 830, the region corresponding to the first pattern layer 811 of the first electrode 810 may have a shape protruded upward, and the region corresponding to the second pattern layer 812 of the first electrode 810 may have a shape protruded upward less than the region corresponding to the first pattern layer 811.

The display apparatus 800 of the present disclosure may have a plurality of regions in the first electrode 810, each with a different height. In one or more embodiments, in descending order of size, the display apparatus 800 may include the first region 810A1 with the first height h1, the second region 810A2 with the second height h2, and the third region 810A3 with the third height h3.

Through these height differences, in the regions corresponding to the first electrode 810, it may be feasible to improve or enhance light efficiency by introducing variations in optical resonance between the first electrode 810 and the second electrode 830 in each region.

As an example, among the regions of the first electrode 810, the region including the center of the region from which light is reflected and extracted forward may be formed with the highest first height h1, allowing the light to be reflected and extracted at a larger angle toward a side surface, and the region farther away from the center of the region from which the light is extracted forward may be formed with the second height h2, which is lower than the first height h1, allowing the light to be reflected and extracted at a smaller angle toward the side surface.

Furthermore, among the regions of the first electrode 810 from which light is reflected and extracted forward, the region adjacent to the edge may be formed with the lowest third height h3, as the first pattern layer 811 and the second pattern layer 812 are not present.

Accordingly, the efficiency of light reflected by the first electrode 810 and extracted may be improved or enhanced. In one or more embodiments, assuming that the structure in FIG. 20 represents a sub-pixel (or pixel), the light reflected from the first electrode 810 may be less likely to be blocked by a light-limiting member on the side surface, and, for example, the pixel defining film 880 or a light-blocking member that may be additionally arranged, thereby improving or enhancing light extraction efficiency along with the light efficiency effect achieved through the optical resonance of the first electrode 810. As a result, the display apparatus 800 may be implemented with improved or enhanced image quality characteristics.

In one or more embodiments, the heterogeneous layer 815 may be arranged in at least one region between the base layer 810a and the first pattern layer 811 and may be formed or composed of a material different from a material of the first pattern layer 811. By utilizing the heterogeneous layer 815, damage to the base layer 810a caused by excessive or substantial etching during the formation of the first pattern layer 811 may be reduced or prevented. In one or more embodiments, because the heterogeneous layer 815 may be formed using a dry etching process instead of a wet etching process, the number or duration of wet etching processes may be reduced, thereby enhancing the effect of reducing damage to the base layer 810a.

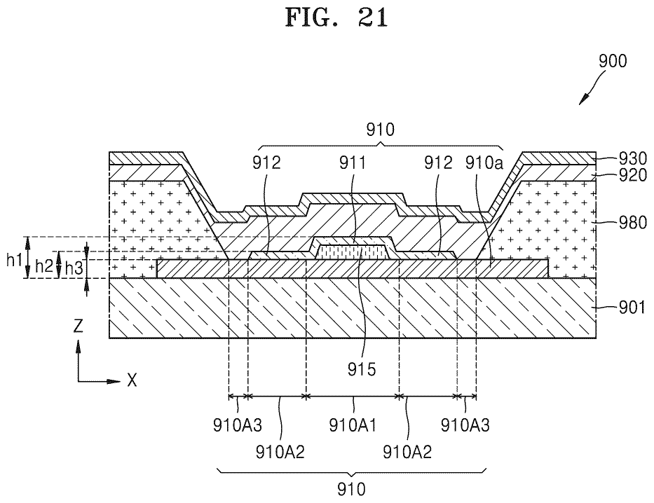

FIG. 21 is a cross-sectional view schematically illustrating a display apparatus according to one or more embodiments of the present disclosure.

Referring to FIG. 21, a display apparatus 900 may include a substrate 901, a first electrode 910, a second electrode 930, and an intermediate layer 920. In one or more embodiments, the display apparatus 900 may further include a heterogeneous layer 915. The heterogeneous layer 915 may overlap at least a portion of the first electrode 810. More details thereof are described herein.

In one or more embodiments, the display apparatus 900 may further include one or more thin-film transistors, a pixel defining film 980, and/or the like arranged on the substrate 901.

For convenience of description, differences from the foregoing embodiments will be mainly or predominantly described herein in more detail.

The substrate 901 may include one or more suitable materials. In more detail, the substrate 901 may be formed or composed of glass, metal, an organic material, and/or other suitable materials, and the details thereof may be modified and applied within a range that is substantially the same or similar to the substrate 101 as described in one or more embodiments, and thus, more detailed descriptions thereof may not be provided.

In one or more embodiments, one or more buffer layers may be arranged on the substrate 901, for example, in a manner similar to the buffer layer 202 of FIG. 2, and a detailed description thereof may be substantially the same as provided in FIG. 2.

In one or more embodiments, one or more thin-film transistors may be arranged as illustrated in FIG. 2.

The first electrode 910 may be arranged on the substrate 901. The thin-film transistor may be arranged substantially the same as described in one more embodiments, and the first electrode 910 may be arranged above (e.g., on) an insulating (e.g., electrically insulating) layer arranged on the thin-film transistor. The first electrode 910 may contain one or more suitable conductive (e.g., electrically conductive) materials, and the materials of the first electrode 910 may be substantially the same as the materials of the first electrode 910 as described in one or more embodiments, and thus, a more detailed description thereof may not be provided.

In one or more embodiments, the first electrode 910 may include a first region 910A1 having a first height h1 with respect to an upper surface of the substrate 901 and second regions 910A2, each of the second regions 910A2 having a second height h2 with respect to the upper surface of the substrate 901.

In one or more embodiments, the second height h2 may have a smaller value than (e.g., may be lower than) the first height h1. In one or more embodiments, it may be seen that the first region 910A1 has a shape that is formed higher or protrudes more than the second region 910A2 with respect to the upper surface of the substrate 901.

In one or more embodiments, the first electrode 910 may include a third region 910A3 having a third height h3 with respect to the upper surface of the substrate 901, and the third height h3 of the third region 910A3 may have a smaller value than (e.g., may be lower than) the second height h2 of the second region 910A2.

The first region 910A1 of the first electrode 910 may be arranged between the second regions 910A2, which are arranged on at least opposite sides of the first region 910A1 of the first electrode 910 (e.g., between two of the second regions 910A2 that are opposite to each other). In one or more embodiments, the first region 910A1 may be surrounded by the second regions 910A2. For example, the first region 910A1 may be arranged in a region including a central portion of a region defined by an opening of the pixel defining film 980 or a central portion of a region defined by an opening of a light-blocking member. The second region 910A2 may be connected to the first region 910A1 and may be around (e.g., surround) the first region 910A1.

The third region 910A3 of the first electrode 910 may be arranged adjacent to the second region 910A2. In one or more embodiments, the third region 910A3 may be adjacent to the second region 910A2 and may be arranged adjacent to a side surface of the second region 910A2 that is opposite to a side surface opposite to (e.g., facing) the first region 910A1.

In one or more embodiments, the third region 910A3 may be formed or arranged in a region in which the first region 910A1 or the second region 910A2 is not formed.

The structure in which the first electrode 910 is arranged on the substrate 901 will be described herein in more detail.

The first electrode 910 may include a base layer 910a, a first pattern layer 911, and a second pattern layer 912.

The base layer 910a may correspond to the entire (e.g., substantially entire) region of the first electrode 910, and, for example, may correspond to the first region 910A1, the second region 910A2, and the third region 910A3.

The first pattern layer 911 may be formed or arranged on the base layer 910a, for example, to be in contact with an upper surface of the base layer 910a, with a (e.g., set or predetermined) thickness.

In one or more embodiments, the heterogeneous layer 915 may be arranged in at least one region between the base layer 910a and the first pattern layer 911. In one or more embodiments, the heterogeneous layer 915 may be arranged on the base layer 910a, and the first pattern layer 911 may be formed or arranged on the heterogeneous layer 915.

At this time, the first pattern layer 911 may be connected to at least the base layer 910a. In one or more embodiments, the first pattern layer 911 may correspond to at least one region of a side surface of the heterogeneous layer 915 and cover the at least one region of the side surface of the heterogeneous layer 915, and, for example, the first pattern layer 911 may cover the heterogeneous layer 915. This may enable smooth electrical connection between the base layer 910a and the first pattern layer 911.

The heterogeneous layer 915 may be formed or composed of a material that is different at least from a material of the first pattern layer 911 and, for example, may be formed or composed of an insulating (e.g., electrically insulating) material. For example, the heterogeneous layer 915 may contain an inorganic material. In one or more embodiments, the heterogeneous layer 915 may be formed or composed of a material that is at least light-transmissive and, for example, may contain a transparent (e.g., substantially transparent) nitride and/or a transparent (e.g., substantially transparent) oxide. In one or more embodiments, the heterogeneous layer 915 may contain silicon nitride (e.g., SiNₓ, wherein 0<x≤2; e.g., Si₃N₄).

By utilizing the heterogeneous layer 915, an optical resonance effect may be maintained through light transmission, and by forming or arranging the heterogeneous layer 915 of a material different from a material of the first pattern layer 911, damage to the base layer 910a due to excessive or substantial etching during the formation of the first pattern layer 911 may be reduced or prevented. In one or more embodiments, during the formation of the first pattern layer 911, damage to the base layer 910a caused by a wet etching process, for example, the dissolution of conductive materials, such as silver (Ag), which may lead to the degradation of an oxide layer (e.g., an ITO layer), may be reduced or prevented.

In one or more embodiments, because the heterogeneous layer 915 may be formed using a dry etching process instead of a wet etching process, the number or duration of wet etching processes may be reduced, thereby enhancing the effect of reducing damage to the base layer 910a.

The second pattern layer 912 may be formed or arranged on the base layer 910a and, for example, may be in contact with the upper surface of the base layer 910a, and may have a thickness less than the total thickness of at least the heterogeneous layer 915 and the first pattern layer 911.

In one or more embodiments, the base layer 910a may have a thickness, which may correspond to the thickness of the third region 910A3. A total thickness of the base layer 910a, the heterogeneous layer 915, and the first pattern layer 911 may correspond to the thickness of the first region 910A1. A total thickness of the base layer 910a and the second pattern layer 912 may correspond to the thickness of the second region 910A2.

By controlling these thicknesses, the first electrode 910 may have different heights in each region.

The first pattern layer 911 and the second pattern layer 912 may be arranged in connection with each other, and, for example, the first pattern layer 911 and the second pattern layer 912 may be laterally connected. For example, the first pattern layer 911 and the second pattern layer 912 may take the form of being integrally connected.

The base layer 910a may be formed or composed of a material different from a material of the first pattern layer 911 and the second pattern layer 912 so as to be distinguished therefrom, and the first pattern layer 911 and the second pattern layer 912 may be formed or composed of substantially the same material.

In one or more embodiments, the base layer 910a may be formed or composed of substantially the same material as the first pattern layer 911 and the second pattern layer 912.

In one or more embodiments, the first region 910A1 of the first electrode 910 may correspond to the base layer 910a, the heterogeneous layer 915, and the first pattern layer 911, the second region 910A2 of the first electrode 910 may correspond to the base layer 910a and the second pattern layer 912, and the third region 910A3 of the first electrode 910 may correspond to the region in which the base layer 910a is present.

The first electrode 910 may include the base layer 910a, the first pattern layer 911, and the second pattern layer 912, with the heterogeneous layer 915 arranged between the first pattern layer 911 and the base layer 910a, thereby facilitating the implementation of height-differentiated regions, which are the first region 910A1, the second region 910A2, and the third region 910A3. In one or more embodiments, through this structure of the first electrode 910, differential resonance structures may be implemented within the pixel, thereby improving or enhancing light efficiency.

The second electrode 930 may be opposite to (e.g., face) the first electrode 910. The second electrode 930 may be formed or composed of one or more suitable conductive (e.g., electrically conductive) materials. In one or more embodiments, the second electrode 930 may contain lithium (Li), calcium (Ca), lithium fluoride (LiF), aluminum (Al), magnesium (Mg), and/or silver (Ag), may be formed or arranged as a single layer or a multilayer of at least one selected from among the foregoing materials, and may include an alloy material containing at least two selected from among the foregoing materials.

The intermediate layer 920 may include an organic light-emitting layer and may be arranged between the first electrode 910 and the second electrode 930. A low-molecular-weight organic material and/or a high-molecular-weight organic material may be utilized for the organic light-emitting layer of the intermediate layer 920. In one or more embodiments, the intermediate layer 920 may further include at least one selected from the group consisting of a hole injection layer, a hole transport layer, an electron transport layer, and an electron injection layer, in addition to the organic light-emitting layer.

After the pixel defining film 980 is arranged so as not to cover a set or predetermined region of the first electrode 910, the intermediate layer 920 may be arranged on the region of the first electrode 910 that is not covered by the pixel defining film 980, and the second electrode 930 may be arranged on the intermediate layer 920.

The pixel defining film 980 may be formed or composed of one or more suitable insulating (e.g., electrically insulating) materials. In one or more embodiments, the pixel defining film 980 may contain an organic material, and, for example, may be formed by a method, such as spin coating utilizing one or more organic insulating (e.g., electrically insulating) materials selected from the group consisting of polyimide, polyamide, an acrylic resin, benzocyclobutene, and a phenol resin.

In one or more embodiments, the pixel defining film 980 may include a material that reduces or blocks the reflection of light incident from the outside, and, for example, may include a black organic material, a dark-colored organic material, and/or a black pigment.

In one or more embodiments, an encapsulation portion may further be arranged, and details thereof may be substantially the same as illustrated in FIG. 2 of one or more embodiments.

In one or more embodiments, the display apparatus 900 may include the features as described in one or more embodiments and, for example, may further include a light-blocking member, a color filter layer, or a cover member, as illustrated in FIG. 2 or FIG. 5.

In one or more embodiments, the display apparatus 900 may include one or more touch pattern layers, such as one or more conductive (e.g., electrically conductive) patterns, and this may be substantially the same as described in one or more embodiments of FIG. 2.

In one or more embodiments, the shape of an upper surface of the first electrode 910 may be at least partially implemented in the intermediate layer 920 and the second electrode 930. In one or more embodiments, among the regions of the second electrode 930, the region corresponding to the first pattern layer 911 of the first electrode 910 may have a shape protruded upward, and the region corresponding to the second pattern layer 912 of the first electrode 910 may have a shape protruded upward less than the region corresponding to the first pattern layer 911.

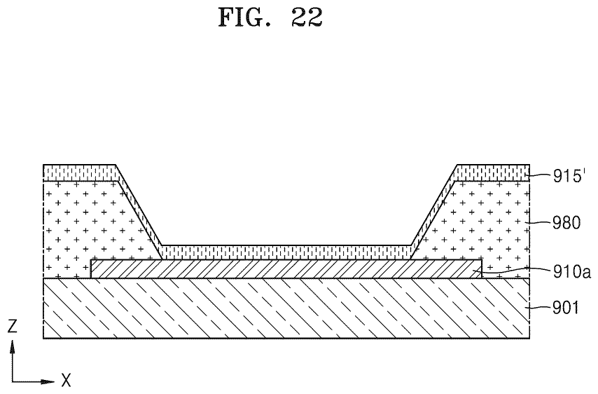

FIGS. 22 to 28 are views schematically describing a method of manufacturing a display apparatus according to one or more embodiments of the present disclosure. For convenience of description, the manufacturing method of the present disclosure illustrates an example of a process of manufacturing the display apparatus of FIG. 21.

Referring to FIG. 22, a base layer 910a may be formed or arranged on a substrate 901. In one or more embodiments, one or more insulating (e.g., electrically insulating) layers may further be between the substrate 901 and the base layer 910a. As another example, a thin-film transistor may further be between the substrate 901 and the base layer 910a. These contents may be substantially the same as described in one or more embodiments.

A pixel defining film 980 may be formed or arranged on the base layer 910a, and the pixel defining film 980 may have an opening corresponding to at least one region of the base layer 910a.

A preliminary heterogeneous layer 915′ may be formed or arranged on the base layer 910a and, for example, may correspond to the base layer 910a and the pixel defining film 980 without separate patterning. The preliminary heterogeneous layer 915′ may be formed or composed of one or more suitable materials, for example, an insulating (e.g., electrically insulating) material, and, for example, may contain an inorganic material. In one or more embodiments, the preliminary heterogeneous layer 915′ may be formed or composed of a material that is at least light-transmissive and, for example, may contain a transparent (e.g., substantially transparent) nitride and/or a transparent (e.g., substantially transparent) oxide. In one or more embodiments, the heterogeneous layer 915 may contain silicon nitride (e.g., SiNₓ, wherein 0<x≤2; e.g., Si₃N₄).

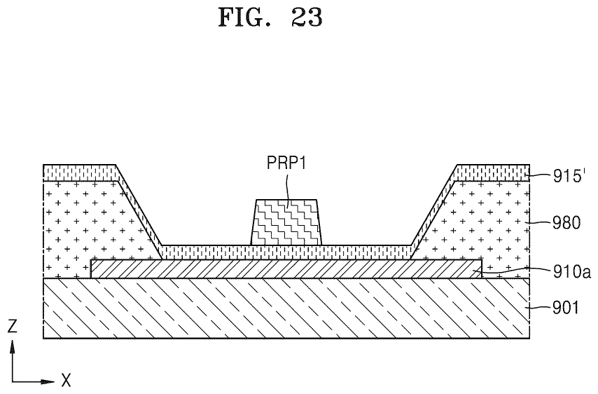

Thereafter, referring to FIG. 23, a first patterning member PRP1 may be formed. The first patterning member PRP1 may be an etch-resistant mask that blocks etching, and may include, for example, a photoresist that may be patterned by photolithography and/or the like.

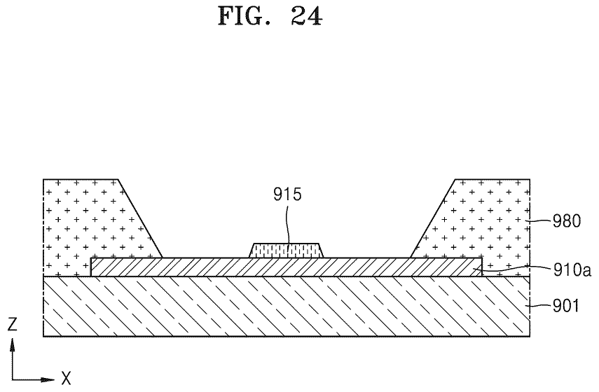

Referring to FIG. 24, the heterogeneous layer 915 may be formed by performing a patterning process utilizing the first patterning member PRP1, such as an etching process. For example, the patterning process may be a dry etching process (e.g., dry etch). Through this dry etching process, damage to the underlying base layer 910a may be reduced, and, for example, damage caused by the dissolution of conductive (e.g., electrically conductive) materials, such as silver (Ag), in the base layer 910a may be reduced or prevented.

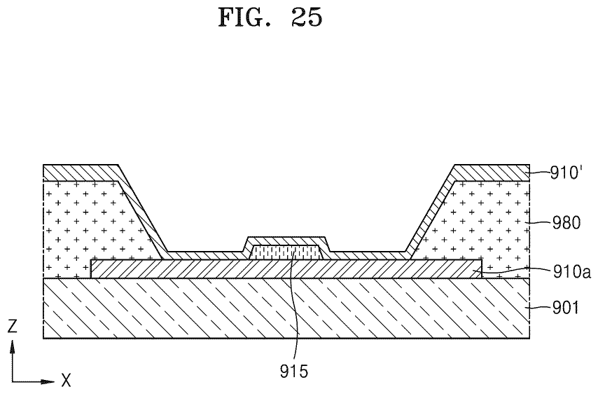

Thereafter, referring to FIG. 25, a preliminary pattern layer 910′ may be formed or arranged on the base layer 910a. The base layer 910a and the preliminary pattern layer 910′ may be formed or composed of different materials so as to be distinguished from each other. In one or more embodiments, both (e.g., simultaneously) the base layer 910a and the preliminary pattern layer 910′ may contain one or more suitable conductive (e.g., electrically conductive) materials, for example, utilizing one of the materials selected from the group consisting of transparent (e.g., substantially transparent) conductive (e.g., electrically conductive) oxides, such as indium tin oxide (ITO), indium zinc oxide (IZO), zinc oxide (e.g., ZnOₓ, wherein 0<x≤2; e.g., ZnO), indium oxide (e.g., In₂O₃), indium gallium oxide (IGO), and aluminum zinc oxide (AZO). As an example, the base layer 910a may contain indium tin oxide (ITO), while the preliminary pattern layer 910′ may contain indium zinc oxide (IZO).

In one or more embodiments, the preliminary pattern layer 910′ may cover the heterogeneous layer 915.

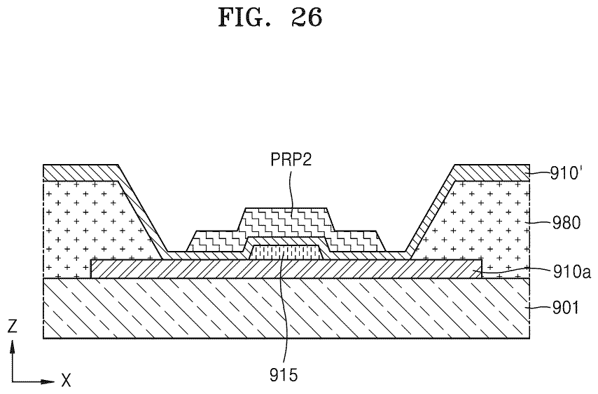

Thereafter, referring to FIG. 26, a second patterning member PRP2 may be formed. The second patterning member PRP2 may be an etch-resistant mask that blocks etching, and may include, for example, a photoresist that may be patterned by photolithography and/or the like.

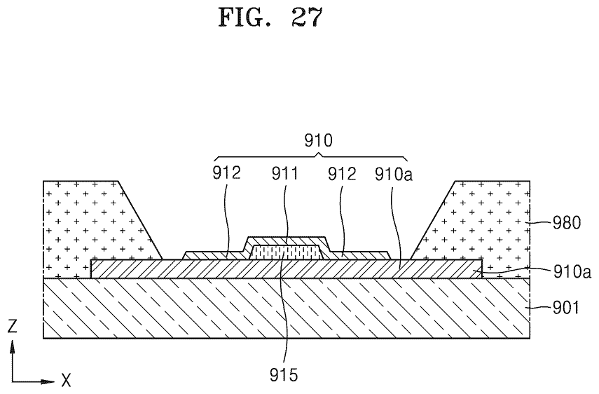

Referring to FIG. 27, an etching process, such as a wet etching process, may be performed utilizing the second patterning member PRP2, thereby forming a first pattern layer 911 and a second pattern layer 912 on the base layer 910a.

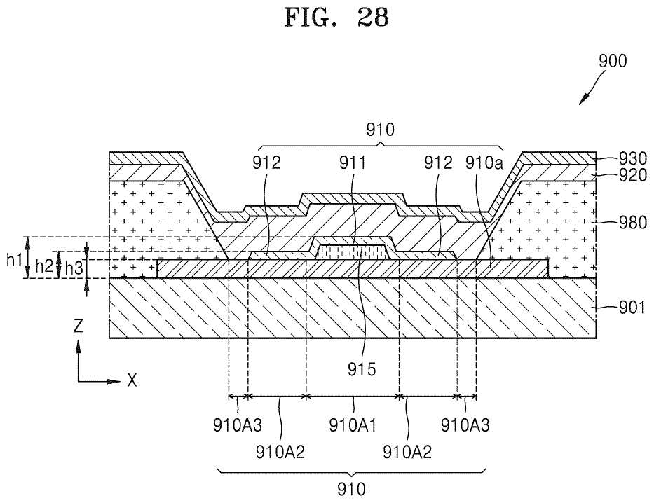

Referring to FIG. 28, an intermediate layer 920 and a second electrode 930 may be formed, thereby completing a display apparatus 900.

By using the manufacturing method of the present disclosure, precise or suitable shapes of the base layer 910a, the first pattern layer 911, and the second pattern layer 912 of the first electrode 910 may be easily or suitably implemented.

In one or more embodiments, during the formation of the first pattern layer 911 and the second pattern layer 912, the heterogeneous layer 915 may be formed between the first pattern layer 911 and the base layer 910a. Effective or suitable thicknesses of the first pattern layer 911 and the second pattern layer 912 may be controlled or selected to be substantially identical or similar to each other by adjusting a thickness of the heterogeneous layer 915. As a result, the patterning of conductive (e.g., electrically conductive) layers of the first pattern layer 911 and the second pattern layer 912, such as the patterning of IZO, may be performed with a reduced wet etching process time and/or fewer process steps. In one or more embodiments, the patterning of conductive (e.g., electrically conductive) layers may involve only a single wet etching process. Through the reduction of such a wet etching process, damage to the base layer 910a may be reduced or prevented. In one or more embodiments, the dissolution of conductive (e.g., electrically conductive) metal components, such as Ag, contained within the base layer 910a, may be reduced or prevented, thereby avoiding surface damage and deformation (or reducing a degree or occurrence of surface damage and deformation) of the base layer 910a.

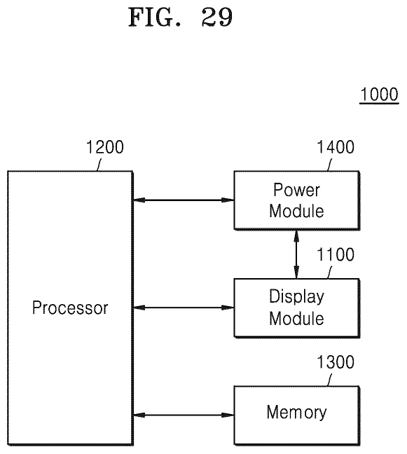

FIG. 29 is a diagram describing an electronic device to which the display apparatus according to one or more embodiments of the present disclosure is applied.

The display apparatus according to one or more embodiments of the present disclosure may be applied to one or more suitable electronic devices. In one or more embodiments, the electronic device may include one or more display apparatuses as described in one or more embodiments of the present disclosure and may optionally further include modules or devices with additional functions other than the display apparatus.

Referring to FIG. 29, an electronic device 1000 according to one or more embodiments may include a display module 1100, a processor 1200, a memory 1300, and a power module 1400.

The processor 1200 may include at least one selected from among a central processing unit (CPU), an application processor (AP), a graphic processing unit (GPU), a communication processor (CP), an image signal processor (ISP), and a controller.

The memory 1300 may be to store data information necessary or desired for the operation of the processor 1200 or the display module 1100. If (e.g., when) the processor 1200 executes an application stored in the memory 1300, a video data signal and/or an input control signal may be transmitted to the display module 1100, and the display module 1100 may be to process the received signal and output video information through a display screen.

The power module 1400 may include a power supply module, such as a power adapter or a battery device, and a power conversion module that is to convert power supplied by the power supply module to generate power desired or required for the operation of the electronic device 1000.

At least one selected from among the components of the electronic device 1000 may be included in the display apparatus according to one or more embodiments. In one or more embodiments, among individual modules functionally included within one module, one or more suitable modules may be included in the display apparatus, while others may be provided separately from the display apparatus. In one or more embodiments, the display apparatus may include the display module 1100, and the processor 1200, the memory 1300, and the power module 1400 may be provided in the form of separate devices within the electronic device 1000 rather than as part of the display apparatus.

In one or more embodiments, the electronic device 1000 may be provided in a form in which the display apparatus as described in one or more embodiments of the present disclosure is included in the display module 1100.

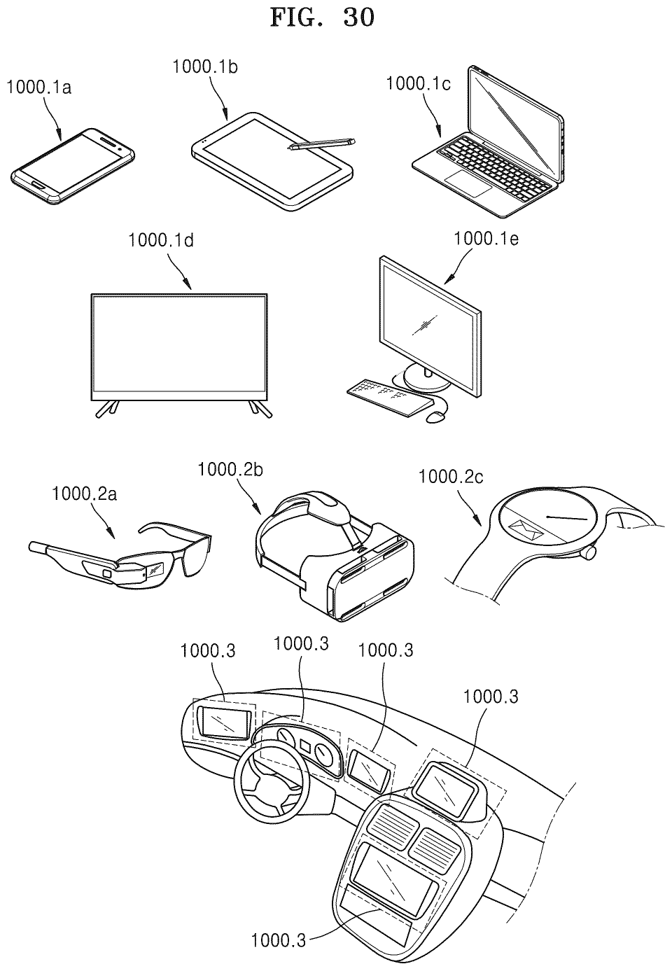

FIG. 30 is a drawing illustrating one or more suitable examples of the electronic device of FIG. 29.

Referring to FIG. 30, one or more suitable electronic devices to which the display apparatuses as described in one or more embodiments of the present disclosure are applied may include image display electronic devices, such as a smartphone 1000.1a, a tablet personal computer (PC) 1000.1b, a laptop 1000.1c, a TV 1000.1d, and a desktop monitor 1000.1e.

In one or more embodiments, one or more suitable electronic devices to which the display apparatuses as described in one or more embodiments of the present disclosure are applied may include wearable electronic devices that include a display module, such as smart glasses 1000.2a, a head-mounted display 1000.2b, and a smart watch 1000.2c.

In one or more embodiments, one or more suitable electronic devices to which the display apparatus as described in one or more embodiments of the present disclosure is applied may include vehicle electronic devices 1000.3 that include a display module, such as an instrument panel, a center information display (CID) arranged in the center fascia or dashboard, and a room mirror display.

In a display apparatus and a method of manufacturing a display apparatus according to one or more embodiments of the present disclosure, improved or enhanced image quality characteristics and precise or suitable control of optical characteristics may be implemented.

While the subject matter of the present disclosure has been described in connection with what is presently considered to be practical example embodiments, it is to be understood that the present disclosure is not limited to the disclosed embodiments, but, in one or more embodiments, is intended to cover one or more suitable modifications and equivalent arrangements included within the spirit and scope of the appended claims and equivalents thereof. It therefore will be understood that one or more embodiments described herein are just illustrative but not limitative in all aspects.

What is claimed is:

1. A display apparatus comprising:
a substrate;
a first electrode on the substrate;
a second electrode opposite to the first electrode; and
an intermediate layer between the first electrode and the second electrode and comprising an organic light-emitting layer,
wherein the first electrode comprises:
a first region having a first height with respect to an upper surface of the substrate; and
second regions, each of the second regions having a second height that is lower than the first height.

2. The display apparatus as claimed in claim 1, wherein the first region is between two of the second regions that are opposite to each other.

3. The display apparatus as claimed in claim 1, wherein the first region is surrounded by the second regions.

4. The display apparatus as claimed in claim 1, wherein the first region is spaced from the second regions.

5. The display apparatus as claimed in claim 1, wherein:
the first electrode comprises:
a base layer;
a first pattern layer on the base layer; and
a second pattern layer on the base layer,
the first region corresponds to the base layer and the first pattern layer, and
each of the second regions corresponds to the base layer and the second pattern layer.

6. The display apparatus as claimed in claim 1, further comprising a light-blocking member on the second electrode, the light-blocking member comprising an opening region to allow light generated in the intermediate layer to pass therethrough, and
wherein the first region and the second regions of the first electrode overlap the opening region.

7. The display apparatus as claimed in claim 1, wherein:
the first region of the first electrode corresponds to a region comprising a central portion of the opening region; and
the second regions are around the first region.

8. The display apparatus as claimed in claim 1, wherein the first region is connected to the second regions.

9. The display apparatus as claimed in claim 1, further comprising at least one or more intermediate regions between the first region and the second region, the at least one or more intermediate regions comprising regions having at least one or more heights between the first height and the second height.

10. The display apparatus as claimed in claim 1, further comprising one or more insulating layers between the substrate and the first electrode.

11. The display apparatus as claimed in claim 1, further comprising one or more thin-film transistors between the substrate and the first electrode.

12. The display apparatus as claimed in claim 1, wherein the first electrode comprises:
a base layer having one or more curved portions; and
a pattern layer on the base layer.

13. The display apparatus as claimed in claim 12, wherein each of the one or more curved portions comprises a convex surface protruded in a direction toward the second electrode.

14. The display apparatus as claimed in claim 12, wherein an upper surface of the pattern layer opposite to the second electrode has a flat surface in at least one region of the upper surface of the pattern layer.

15. The display apparatus as claimed in claim 12, wherein the one or more curved portions and the pattern layer do not overlap each other.

16. A method comprising:
forming a first electrode;
forming a base layer of the first electrode on a substrate; and
forming a pattern layer having one or more patterns on the base layer,
wherein the method is a method of manufacturing a display apparatus.

17. An electronic device comprising:
a processor to execute one or more applications; and
a display apparatus to implement one or more images through the processor, and
wherein the display apparatus comprises:
a substrate;
a first electrode on the substrate;
a second electrode opposite to the first electrode; and
an intermediate layer between the first electrode and the second electrode and comprising an organic light-emitting layer, and
wherein the first electrode comprises:
a first region having a first height with respect to an upper surface of the substrate; and
second regions, each of the second regions having a second height that is lower than the first height.

18. The electronic device as claimed in claim 17, further comprising a power module to generate a power to operate a memory that stores data information for an operation of the processor or the display apparatus or to operate the electronic device.

19. The electronic device as claimed in claim 17, wherein the first electrode comprises:
a base layer having one or more curved portions; and
a pattern layer on the base layer.

20. The electronic device as claimed in claim 17, wherein the electronic device is applied to an image display electronic device, a wearable electronic device, or a vehicle electronic device.
